(19) United States
(12) Patent Application Publication
(10) Pub. No.: US 2016/0289826 A1
(43) Pub. Date: Oct. 6, 2016

(54) METHOD FOR CONTINUOUS PRODUCTION OF ALIGNED NANOSTRUCTURES ON A RUNNING SUBSTRATE AND RELATED DEVICE

(71) Applicant: COMMISSARIAT À L'ÉNERGIE ATOMIQUE ET AUX ÉNERGIES ALTERNATIVES, Paris (FR)

(72) Inventors: Pascal BOULANGER, Eguilles (FR); Martine MAYNE, Les Molieres (FR); Mathieu PINAULT, Antony (FR); Emeline CHARON, Paris (FR); Cecile REYNAUD, Cachan (FR)

(73) Assignee: COMMISSARIAT À L'ÉNERGIE ATOMIQUE ET AUX ÉNERGIES ALTERNATIVES, Paris (FR)

(21) Appl. No.: 15/036,723

(22) PCT Filed: Nov. 14, 2014
(86) PCT No.: PCT/EP2014/074600

§ 371 Date: May 13, 2016

(30) Foreign Application Priority Data
Nov. 14, 2013 (FR) 13 61119

(51) Int. Cl. C23C 16/455; B01J 31/22; C01B 31/02

(52) U.S. Cl. CPC C23C 16/455; C01B 31/0233; B01J 31/2295; C01B 2202/08; B01J 2231/005; B01J 2531/842; B82Y 40/00

(57) ABSTRACT

The invention relates to a method for continuously manufacturing aligned nanostructures on a running support, which comprises conveying the support through a heated space and synthesising, in this space, aligned nanostructures on the support by catalytic chemical vapour deposition. The heated space is divided into n consecutive zones in the conveying direction of the support (n being an integer ≧2), and the synthesis of the nanostructures results from heating and injection operations, in each of these n zones, of a flux of an aerosol containing a catalytic precursor and a source precursor of the material of the nanostructures to be formed, carried by a carrier gas. The injection operations are made by modifying, in at least two of the n zones, at least one parameter chosen among the flow rate of the carrier gas flux, the chemical composition of the carrier gas, the mass concentration of the catalytic precursor in the catalytic precursor and source precursor mixture. The invention also relates to a device for implementing this method.

### TECHNICAL FIELD

The present invention relates to continuously manufacturing aligned nanostructures on a running host material, the nanostructures possibly being for example nanotubes or nanowires and the host material possibly being a substrate, a fibre or any other support.

More particularly, the invention relates to a method dedicated to continuously manufacturing aligned nanostructures on a support by catalytic chemical vapour deposition and its related device.

The method and device according to the invention have numerous possible applications. They can for example be used for making aligned nanotubes. Advantageously, the method enables carbon-based aligned nanotubes to be made with or without inserting heteroatoms (heteroatoms being for example phosphorus, boron, or nitrogen). Other tubular structures can also be contemplated as, for example and in a non-exhaustive way, nanowires of boron nitride, titanium dioxide, silicene or else. In the same way, the method and device according to the invention can be used for making aligned nanowires, for example aligned nanowires of silicon or composed of different components as, for example and in a non-exhaustive way, oxides (zinc oxide) or carbides (silicon or zinc carbide).

Such organized nanostructures can advantageously be used, for example, for manufacturing nanoporous membranes (filtration membranes). They can also be used for manufacturing electrodes, composite materials or even for making electronic components and energy converting devices.

### STATE OF PRIOR ART

Nanostructures (namely structures that have at least one characteristic dimension (width, diameter or other) lower than 100 nm) can be made as networks of aligned nanostructures on a support.

This particular arrangement is advantageous, because it enables nanostructures to be manufactured under improved safety conditions with respect to a method which would manufacture nanostructures dispersed and collected as a powder. Indeed, upon growing networks of aligned nanostructures on a support (substrate for example), the nanostructures are integral with the support and, because of their organization and assembly between each other, they are very hardly dispersible in the environment.

Furthermore, this particular arrangement, combined with the fact that the nanostructures have all the same height, makes them interesting relative to nanostructures collected as a powder and having a random organization and a variable length, and facilitates the implementation of these nanostructures for some applications, in the composite materials for example. This particular arrangement further enables, in the particular case of nanotubes and nanowires, their unidirectional properties to be exploited and to be implemented in numerous applications (for example, the manufacture of filtration membranes and electrodes, as set out above).

Today, there are numerous methods which enable networks of nanostructures vertically aligned on a substrate to be synthesised by using the techniques of chemical vapour deposition (CVD). All these methods can however be classified in two groups.

There are, on the one hand, synthesis methods which rely on a pre-deposition of the catalyst onto the support, followed by the growth by CVD of the nanostructures onto the catalyst by feeding a precursor in gaseous form (source of the material of the nanostructures) in the CVD enclosure. The pre-deposition of the catalyst onto the support can be achieved by a physical deposition-type method (by sputtering or by molecular beam epitaxy (MBE) for example or by a chemical deposition-type method (coating, dip-coating, spin-coating, spray, electrodeposition, etc.). By way of example, such a method for synthesising on a running substrate is illustrated in patent applications US 2010/0260933 A1 and US 2013/0045157 A1 (references [1], [2]).

There are, on the other hand, synthesis methods which are carried out by performing a simultaneous and continuous injection or co-injection) of a precursor of the material of the nanostructures (carbon source for carbon nanostructures) and a catalytic precursor onto the support. By way of example, such a method for synthesising on a running substrate is illustrated in patent application US 2009/0053115 A1 (reference [3]).

It turns out that, for continuously making aligned nanostructures on a support, the synthesis by co-injecting a source precursor and a catalytic precursor is more suitable than the method requiring a pre-deposition of the catalyst. Indeed, the continuous feed of a source precursor and a catalytic precursor allows for an endless synthesis, as long as the source precursor and the catalytic precursor are injected in the CVD enclosure.

In comparison, the CVD method by pre-deposition is restricted by the lifetime of the catalyst which, in the case of carbon nanotubes, is poisoned by the carbon of the carbon precursor if no adjuvant is added to the carbon source. Recently, adjuvants as oxygen in the form of water vapour have enable the lifetime of the catalysts to be increased and it is thus currently possible to synthesise single sheets carbon nanotubes which are aligned and have controllable thickness. However, even if the continuous growth of aligned nanostructures is possible from the CVD method by pre-deposition, the synthesis by continuously co-injecting a source precursor and a catalytic precursor has the advantage to be capable of being carried out in a single reaction step in a single CVD enclosure (namely a single CVD furnace), because of the simultaneous feed of the source precursor and of the catalytic precursor. Finally, the synthesis par co-injection is preferable for cost and safety reasons.

It is worth noting that some synthesis methods relying on a pre-deposition can have a sequence of both pre-deposition and growth steps. However, the complexity of the sequence of the steps is very great, with for example treatment phases of the pre-deposition, which will strongly slow down the running speed of the support and thus decrease the productivity and increase the cost of nanostructures thus made on this support.

On the other hand, it is known that in the case of a synthesis of carbon nanotubes by the method of co-injecting the catalyst, it is possible to have an influence on the morphological and structural characteristics of the nanotubes by modifying the synthesis conditions. Thereby, it is known that the diameter of the nanotubes is influenced by the presence of hydrogen (reference [4]), their density is influenced by the mass percentage of the catalytic precursor and their length is in turn influenced by the synthesis time period (reference [5]).

Hence, the inventors attempted to know what would happened if, rather than modifying the synthesis conditions of the nanotubes between two distinct syntheses, the synthesis conditions were modified during a same continuous synthesis, in particular by running the support of the nanostructures and/or dramatically reducing the content of the catalytic precursor during the synthesis.

Thereby, it is during their experimentations, that the inventors have observed that by making syntheses with very low, and preferably constant, concentration, of the catalytic precursor (typically between 0.05 and 0.5% by weight), the catalytic yield of the synthesis and the growth speed of the carbon nanostructures dramatically increase and, consequently, that the iron content dramatically decreases. By way of example, an increase factor from 20 to 25% for the catalytic yield, an increase factor of 2.5% for the growth speed and a decrease factor from 20 to 25% for the iron content are obtained for a synthesis of carbon nanostructures with 0.1% by weight of ferrocene, as compared with a synthesis with 2.5% by weight of ferrocene.

The inventors have also observed that by starting a synthesis from a solution of precursors containing a high concentration of the catalytic precursor (typically 2.5% by weight) for a period of time up to a few minutes (typically from 0.5 to 2 minutes), and then by strongly reducing this concentration of the catalytic precursor (typically up to values of 0.01% by weight) for a period of time at least twice longer, the overall yield and the growth speed of the carbon nanostructures are increased. By way of example, an increase from 3 to 37% for the overall yield and from 11 to 26% for the growth speed are achieved depending on the injection time period of the solution with a high catalytic precursor concentration (30 s or 1 min 40, the low concentration solution being injected for respective time periods of 14 min 30 or 13 min 20), as compared with a single injection with a low catalytic precursor concentration (typically 0.1% by weight) for 15 minutes during the synthesis of carbon nanostructures.

Thus, the inventors have observed that modifying the operating conditions during a synthesis by co-injection, and in particular decreasing the concentration of the catalytic precursor to very low values (typically from 1% to 0.01% by weight), can strongly impact the purity of the carbon nanostructures, as well as the overall yield and the growth speed.

In parallel thereto, the inventors have attempted to provide a synthesis method, and to design an associated device, enabling aligned nanostructures to be manufactured at an industrial scale, taking into account a lower cost and increased productivity purpose. For this, they have judiciously decided to design a device and a method enabling time synthesis conditions namely different synthesis conditions over time) to be transposed into spatial synthesis conditions (namely different synthesis conditions as a function of the location of the support in the device) of nanostructures on a support. By transposing the operating synthesis conditions varying over time into synthesis operating conditions spatially varying, it is then possible to achieve a continuous production of aligned nanostructures on a running substrate.

All the scientific and technical observations above, as well as the design of a device enabling spatial variable synthesis conditions to be achieved, are the object of the invention.

### DISCLOSURE OF THE INVENTION

The invention thus first relates to a method for continuously manufacturing aligned nanostructures on a running support, comprising conveying the support through a heated space and synthesising, in this space, aligned nanostructures on the support by catalytic chemical vapour deposition. The method is characterised in that, the heated space being divided into n consecutive zones in the conveying direction of the support, n being an integer higher than or equal to 2, the synthesis of the nanostructures result from heating operations and injection operations, in each of the n zones, of a flux of an aerosol containing a catalytic precursor and a source precursor of the material of the nanostructure to be formed, carried by a carrier gas and in that the injection operations are made by modifying, in at least two of the n zones, at least one parameter chosen among the flow rate of the carrier gas flux, the chemical composition of the carrier gas, the mass concentration of the catalytic precursor in the catalytic precursor and source precursor mixture. By proceeding this way, synthesis conditions of the nanostructures which are different in at least two of the n zones are achieved.

The carrier gas can be an inert gas or a reactive gas; the aerosol per se corresponds to the dispersion, as droplets, of the liquid or the solution containing the catalytic precursor and/or the source precursor in the carrier gas, this dispersion being achieved by spraying or nebulising the liquid or the solution into the carrier gas.

It is to be noted that, in what follows, the mass concentration of the catalytic precursor is always, and even when this is not specified, its mass concentration in the mixture of precursors (source precursor+catalytic precursor). By “source precursor”, it is meant a solid, liquid or gas compound, being the precursor of the material of the nanostructures to be formed.

Within the scope of the present invention, by “continuously manufacturing and on a running support”, it is meant manufacturing in which both following elements are carried out:
an injection for which all the precursors (catalytic and source) are simultaneously injected (co-injection) or for which each of the precursors is separately injected, this injection being carried out in any case without interruption (continuously over time) upon growing the nanostructures on the support (substrate or other), in opposition with a pre-deposition-type synthesis which is divided into a step of pre-depositing a catalyst onto the support, and then a step of growing the nanostructures onto the catalyst from a source precursor;
a conveyance of the substrate such that the substrate continuously remains in the reaction synthesis zone at a constant non-zero speed, when the substrate is as a single piece; in the particular case of the conveyance of a substrate in several successive pieces (plates to plates, for example) it can correspond to a running speed momentarily equal to zero, the substrate being then conveyed in the reaction zone and stopped when it is at the desired place to start the injection.

It is to be noted that the residence time of the support in a zone n is a function of the running speed of the support and is defined as being the size L (length in the running direction) of a synthesis zone n divided by the running speed V of the substrate. A sequence synthesis of X steps with a time period T₁ to Tₓ on a fixed substrate can thus be translated as equivalent to as synthesis on X adjacent zones having a size L₁ to Lₓ such that Lᵢ=V×Tᵢ (for any i from 1 to X).

Advantageously, the aligned nanostructures as a carpet are of carbon, the catalytic precursor is a transition metal metallocene (preferably an iron, cobalt or nickel metallocene) and the source precursor is a hydrocarbon (preferably toluene, benzene, xylene, cyclohexane, or hexane). Preferably, the catalytic precursor is ferrocene and the source precursor is toluene.

Advantageously, the catalytic precursor injected in the n zones has a mass concentration in the catalytic precursor and source precursor mixture which is constant.

According to a first possible alternative of the method object of the invention, the catalytic precursor injected has, in at least one of the n zones, a mass concentration in the catalytic precursor and source precursor mixture which is higher than or equal to 0.01% by weight and lower than or equal to 1% by weight. Preferably, the catalytic precursor injected in said at least one of the n zones has a mass concentration in the catalytic precursor and source precursor mixture which is higher than or equal to 0.05% by weight and lower than or equal to 0.5% by weight.

According to one preferred embodiment of this first alternative in which the catalytic precursor is ferrocene and the source precursor is toluene, the concentration of ferrocene present in the catalytic precursor and source precursor mixture (ferrocene and toluene mixture) is between 0.05% and 0.5% by weight. In this range of values, the inventors have observed that the catalytic synthesis yield and the growth speed of the nanostructures dramatically increase, thus dramatically decreasing the iron content (and increasing the purity of the nanostructures). Preferentially, the concentration of ferrocene is between 0.1% and 0.25% by weight, in which range the catalytic yield and the growth speed achieved are the highest, which has a significant advantage in terms of production and purity of the carbon nanostructures.

The overall yield is defined as being equal to the ratio of the total mass of the product obtained (typically carbon and iron for carbon nanostructures) to the total mass of the precursors injected (catalytic precursor and source precursor of the nanostructures).

The growth speed is in turn defined as being equal to the ratio of the total length of the nanostructures (which, in our case, also corresponds to the thickness of the carpet of nanostructures) to the total growth time period.

Finally, the purity is defined as being equal to the ratio of the mass of the characteristic element of the product obtained (typically carbon for carbon nanostructures) to the total mass of the product obtained. In other words, the purity of the product obtained can also be evaluated from the mass concentration of the residual catalyst in the final product, which has to be lower than 5% by weight, preferentially lower than 3% by weight, ideally lower than 1% by weight.

According to a second possible alternative of the method object of the invention, assuming the centre of the n zones of the device, the total mass concentration of the catalytic precursor present in the catalytic precursor and source precursor mixture injected as an aerosol in the zone or all the zones located upstream of the centre along the conveying direction is at least twice higher than the total mass concentration of the catalytic precursor present in the catalytic precursor and source precursor mixture injected as an aerosol in the zone or all the zones located downstream of the centre along the conveying direction.

According to a third possible alternative of the method object of the invention, the mass concentration of the catalytic precursor in the catalytic precursor and source precursor mixture injected as an aerosol in one of the n zones called the high concentration zone) is at least twice higher than the mass concentration of the catalytic precursor in the catalytic precursor and source precursor mixture injected as an aerosol in each of the remaining n−1 zones.

Preferably, the high concentration zone is the first zone along the conveying direction.

By total concentration of the catalytic precursor in the zone or all the zones located upstream (downstream) of the centre, it is meant the sum of the concentrations of the catalytic precursor in the zone(s) located upstream (downstream) of the centre.

According to a preferred embodiment of this third alternative, the mass concentration of the catalytic precursor present in the catalytic precursor and source precursor mixture injected as an aerosol in the high concentration zone is between 2% by weight and the saturation limit of the catalytic precursor in the source precursor (this value varies as a function of the catalytic precursor and the source precursor; for example, it is in the order of 15% by weight of ferrocene in toluene) and the mass concentration of the catalytic precursor present in the catalytic precursor and source precursor mixture injected as an aerosol in the remaining n−1 zones is lower than or equal to 1% by weight. Preferably, the mass concentration of the catalytic precursor which is injected in the high concentration zone is between 2.5 and 10% by weight, preferentially up to 5% by weight, and the mass concentration of the catalytic precursor which is injected in the other n−1 zones is lower than or equal to 0.1% by weight.

According to a preferred embodiment of this third alternative in which the catalytic precursor is ferrocene and the source precursor is toluene, the concentration of ferrocene present in the catalytic precursor and source precursor mixture (ferrocene/toluene mixture) which is injected as an aerosol in the catalytic precursor high concentration zone is between 0.5 and 10% by weight, preferably between 1 and 5% by weight, and the concentration of ferrocene present in the catalytic precursor and source precursor mixture injected as an aerosol in the other zones is lower than or equal to 0.5% by weight, preferably lower than or equal to 0.25% by weight and more preferentially lower than or equal to 0.1% by weight.

This third alternative results from the observation of the inventors that by starting a synthesis from a solution of precursors containing a high concentration of the catalytic precursor (typically 2.5% by weight) for a few minutes (typically 0.5 to 2 minutes), and then by strongly reducing this concentration of the precursor (typically up to values of 0.01% by weight), the overall yield and the growth speed were increased. By way of example, an increase from 3 to 37% for the overall yield and from 11 to 26% for the growth speed are achieved depending on the injection time period of the solution with a high catalytic precursor concentration (30 s or 1 min 40, the low concentration solution being injected for respective time periods of 14 min 30 or 13 min 20), as compared with a single injection with a low catalytic precursor concentration (typically 0.1% by weight for 15 minutes).

It can also be noted that the catalytic chemical vapour deposition (CCVD) which is used to make the nanostructures is a known deposition method and is thus not described herein in detail. It enables localised deposits to be made (with a controlled thickness substantially as a function of the precursor injection time period) from, for example, liquid chemical precursors or solid precursors soluble in a liquid which plays or not the role of a source precursor of the nanostructures to be formed, the precursors being injected as aerosols which are vaporised, and then transformed by thermal and/or catalytic decomposition to give rise to the nanostructures.

According to another possible alternative of the method object of the invention, the injection operations being made by modifying, in at least two of the n zones, at least one parameter chosen among the flow rate of the carrier gas flux, the chemical composition of the carrier gas, the mass concentration of the catalytic precursor in the catalytic precursor and source precursor mixture, the injection operations are further made by modifying, in at least two of the n zones, the injection flow rate of the catalytic precursor and source precursor mixture. It is to be noted that said at least two zones in which the mixture injection flow rate is modified can be different or not from the at least two zones in which at least one parameter, chosen among the flow rate of the carrier gas flux, the chemical composition of the carrier gas and the mass concentration of the catalytic precursor in the catalytic precursor and source precursor mixture, is modified.

Advantageously, in the method object of the invention, the heating operations are carried out at a different temperature in at least two of the n zones.

Advantageously, the synthesis of the nanostructures further results from injection operations of a flux of at least one reactive liquid in at least one of the n zones. Within the scope of the present invention, by “reactive fluid”, it is meant any gas or liquid intervening in the synthesis of the nanostructures. The reactive fluid can for example be chosen among water (H₂O), ammonia (NH₃), nitrogen (N₂), dihydrogen (H₂), acetylene (C₂H₂), methane (C₂H₄), ethylene (CH₃) and carbon dioxide (CO₂).

The invention also relates to a device specially designed for the implementation of the method as described above. This device comprises:
an enclosure, provided with an inlet and an outlet through which the support enters and exits respectively;
a reaction chamber (corresponding to the heated space mentioned in the method), located in the enclosure between the inlet and the outlet, and divided into n zones, along the conveying direction, n being an integer higher than or equal to 2;
means for conveying, along the conveying direction, the support from the inlet to the outlet of the enclosure passing through the reaction chamber.

This device is characterised in that each zone is equipped with:
a first injecting system for injecting, in the associated zone, a flux of an aerosol containing a catalytic precursor and a source precursor of the material of the nanostructures to be formed, carried by a carrier gas;
a first individual heating element, configured to heat the substrate upon passing in the associated zone;
a second individual heating element, configured to heat the aerosol injected in the associated zone.

The device according to the invention has the advantage to allow for an industrial production of aligned nanometric structures, with an attractive cost and at an increased productivity, since the production of the nanostructures is achieved on a running substrate. Thanks to this device, it is possible to transpose synthesis operating conditions variable over time into spatial variable synthesis conditions, for a continuous production of aligned nanostructures on a running substrate.

Advantageously, at least two of the n first injecting systems are configured to inject the aerosol with a parameter, chosen among the carrier gas flow rate and the mass concentration of the catalytic precursor in the catalytic precursor and source precursor mixture, which is different.

According to one alternative, at least one of the n zones is further equipped with a second injecting system for injecting, into the associated zone, a flux of at least one reactive fluid. Preferably, each of the n zones is equipped with a second injecting system. Advantageously, at least two of the n zones are equipped with a second injecting system and at least two of these second injecting systems are configured to inject the reactive fluid(s) in the associated zones, with a parameter, chosen among the flow rate of the reactive fluid(s), the chemical composition and the concentration of the different components of the reactive fluid(s), which is different.

According to another alternative, the flux of the aerosol containing a catalytic precursor and a source precursor of the material of the nanostructures to be formed is simultaneously injected with the carrier gas and/or the flux of the reactive fluid.

Preferably, the flux of the aerosol and, if present, the flux of the reactive fluid(s), are injected along a direction substantially perpendicular (namely with 90°+/−30°), preferably perpendicular, to the conveying means, and thus to the support, which enables the deposition of the majority of the reagents to be concentrated at the surface of the support.

The heating of the first and second heating elements can be achieved by convection, induction, conduction, or radiation. Thus, in each of the n zones, the local growth conditions of the nanostructures are determined by the parameters relative to the aerosols and to possible reactive fluids which are injected therein (type of aerosols and reactive fluids injected, flux and concentration of a component in the dissolution or dilution medium), the injection conditions (the injection possibly being continuous or pulsed), as well as the temperature conditions, each zone having its own heating means and the temperature thus being adaptable. It is to be noted that it is possible to assist growth of the nanostructures by additional means, as for example employing an electric field or a plasma, which can be applied independently on each zone.

Advantageously, the device further comprises injection control means, associated with each first injecting system, which are designed to trigger injection of an aerosol flux in the associated zone when the support penetrates this zone and to keep this injection until the support exits from this zone. This enables the raw material consumption to be reduced and thus the manufacturing costs of the aligned nanostructures on a support to be decreased.

Advantageously, at least two adjacent zones are separated from each other by a partition wall having an aperture enabling the support to pass therethrough, containment means being placed at this aperture for preventing fluids and aerosols from passing from one zone to the other. The presence of a partition wall (and of containment means) between two zones is particularly useful when the aerosols and fluids injected are very different (in terms of composition or concentration) from one zone to the other.

Preferably, the zones have along a cross-section plane perpendicular to the conveying direction of the conveying means, a polygonal shape, for example trapezoidal, the short base of which represents the top part of the zone (where are located, preferably, the injectors of the first and second injecting systems, as well as the second heating elements), whereas the long base represents the bottom part of the zone where are located the first heating elements. This particular shape is adapted to the cone shape that the injected fluxes often have: this shape enables a good homogeneity of the deposited materials to be achieved, in particular by adjusting the height of the trapezium.

According to one alternative, the enclosure can further include a pre-treatment chamber, which is located upstream of (namely forwardly) the reaction chamber, along the conveying direction of the support, and which is provided with an inlet and an outlet through which the support enters and exits respectively, the pre-treatment chamber being equipped with a system for injecting the fluid and heating means.

In this pre-treatment chamber, a thin layer is formed from the injected fluid on the support before the nanostructures are formed, for example by chemical vapour deposition (CVD), by atomic layer deposition (ALD), by molecular layer deposition (MLD), by plasma enhanced chemical vapour deposition (PECVD), by low pressure chemical vapour deposition (LPCVD), by electrical field assisted chemical vapour deposition (ELFICVD), by aerosol assisted catalytic chemical vapour deposition (AACCVD), etc. A ceramic layer or a carbon layer (for example graphene) can for example be deposited onto a carbon or steel support.

The presence of a pre-treatment chamber enables the support to be specifically prepared before the nanostructures are synthesised. Care should be taken not to confuse this possible support preparation with a catalyst pre-deposition step. During this pre-treatment, a layer intended to be used as a diffusion barrier layer for the source precursor and the catalytic precursor can for example be deposited between the support and the nanostructures, as set forth in reference [6], or intended to improve the chemical compatibility of the nanostructures with the support. Aligned nanostructures can thus be obtained on any type of support compatible with the nanostructure growth conditions, even on supports on which the nanostructure growth is difficult.

According to another alternative, the enclosure can further include a post-treatment chamber, which is located downstream of (namely behind) the reaction chamber, along the conveying direction of the support, and which is provided with an inlet and an outlet through which the support enters and exits respectively, the post-treatment chamber being equipped with a fluid injecting system and heating means. In this post-treatment chamber, a layer is formed from the injected fluid on the nanostructures, for example by CVD, ALD, MLD, PECVD, LPCVD, ELFICVD, AACCVD, etc. A deposition of a silica layer can for example be made from TEOS (tetraethoxysilane) on aligned carbon nanostructures on a support, which enables a protective encapsulation of the carbon nanotubes to be made, for example in view of a future functionalisation of the nanotubes, or even for safety considerations of the product obtained, this coating enabling the nanotubes to be better attached to their substrate. Depending on the thickness of the layer deposited, this post-treatment enables the partial or total filling of the space between the nanostructures to be achieved.

It is quite possible to have both a pre-treatment chamber and a post-treatment chamber. The pre-treatment, the nanostructure growth and the post-treatment can then be made in the same CVD enclosure.

Preferably, the containment means are located at the inlet and the outlet of the enclosure. If the enclosure includes a pre-treatment chamber and/or a post-treatment chamber, it is also preferable to have containment means at the outlet of the pre-treatment chamber and at the inlet of the post-treatment chamber, in order to prevent a fluid, from one of these two chambers, from passing in either of the n zones of the reaction chamber.

Finally, the method and device according to the invention have many advantages. In particular, they have the advantage that they can be implemented for an industrial synthesis (large scale production), which is sure and applicable to supports having large areas. In particular, with the device according to the invention, a carpet of aligned nanostructures on a support is achieved, wherein the support can be of a large dimension and occupy most of the area available from the conveying means (travelling grid or carpet, for example) or being of smaller dimensions, then making it possible to have several supports close to each other on the conveying means. The method and device according to the invention also enable any direct contact of the operator with the nanostructures during their synthesis to be avoided. It also enables any direct contact of the operator with the nanostructures during their shaping to be avoided, if the deposition of a protective layer onto the nanostructures in a post-treatment chamber is carried out. Thus, no direct human manipulation of the nanostructures is required. Finally, a same device can be used to manufacture several aligned nanostructures on a support: the aerosols and reactive fluids introduced into the n zones of the reaction chamber simply have to be modified as a function of the intended manufacturing. Further, since each zone has its own injecting systems and its own heating elements, it is possible to adapt the injections and temperatures in each of the n zones of the reaction chamber. It is thus easy, with the device according to the invention, to make several types of aligned nanostructures on a support.

Further, as seen above, the modification of the operating conditions during the synthesis, in particular the decrease in the concentration of the catalytic precursor up to very low values (typically 0.01% by weight), allows for dramatically changing the purity of the carbon nanostructures, the overall yield and/or the growth speed. Finally, the choice between the first, second and third alternatives of the method according to the invention is made the following way:
if it is desired to obtain the purest products possible (namely with more than 95% by weight carbon, or even more than 99%) while meeting growth speeds compatible with an industrial method (≧20 μm/min), a synthesis will be favoured by steadily injecting very small amounts of the catalytic precursor (first alternative);
whereas if it is desired to increase the growth speed and the overall yield, a synthesis will be favoured where the amounts of precursors vary during the synthesis (second and third alternatives).

The invention will be better understood upon reading the complementary description that follows, which relates to:
exemplary embodiments of carbon nanotube carpets obtained by varying synthesis conditions over time on a fixed substrate, these examples enabling to highlight the good results achieved by performing syntheses with very low concentrations of the catalytic precursor;
exemplary operating modes for making carbon nanotube carpets obtained by varying synthesis conditions in space on a substrate running in this space;
possible exemplary embodiments of profiles for injecting species in the n zones by using the device and the method according to the invention.

Of course, these examples are only given by way of illustration of the object of the invention and should in no way be construed as limiting this object.

### BRIEF DESCRIPTION OF DRAWINGS

FIG. 1 represents a schematic cross-section view of the device according to one embodiment of the present invention.

FIG. 2 represents a schematic cross-section view of the device according to another embodiment of the present invention.

FIG. 3 represents a schematic cross-section view taken along the line I-I of FIG. 1.

FIGS. 4a, 4b and 4c are graphs respectively showing the variations in the nanotube iron content (FIG. 4a), catalytic yield (FIG. 4b) and growth speed (FIG. 4c) as a function of the injected ferrocene content, the nanotubes being obtained according to a time mode co-injection synthesis protocol, based on the injection of a constant concentration of ferrocene during one single sequence.

FIGS. 5a and 5b represent pictures of aligned carbon nanotubes of a carpet obtained according to a time mode co-injection synthesis protocol based on the injection of a constant concentration of ferrocene during one single sequence and observed by scanning electron microscopy (SEM) according to two different magnifications.

FIG. 6 represents a spectrum obtained by Raman spectroscopy of a sample of nanotubes obtained according to a time mode co-injection synthesis protocol based on the injection of a constant concentration of ferrocene during one single sequence.

FIG. 7 shows the ratios of the intensity of the band D to the intensity of the band G (I_{D}/I_{G}) of the samples obtained according to a time mode co-injection synthesis protocol based on the injection of a constant concentration of ferrocene during one single sequence.

FIG. 8 represents a picture observed by TEM (transmission electron microscopy) of a sample of nanotubes obtained according to a time mode co-injection synthesis protocol based on the injection of a constant concentration of ferrocene during one single sequence.

FIGS. 9a and 9b are respectively distribution histograms of the external and internal diameters of the nanotubes obtained according to a time mode co-injection synthesis protocol based on the injection of a constant concentration of ferrocene during one single sequence.

FIGS. 10a and 10b are pictures of aligned carbon nanotubes of a carpet obtained according to a time mode co-injection synthesis protocol based on the injection at 800° C. for 15 minutes of a toluene/ferrocene mixture (10% by weight) in the presence of a gas mixture Ar/H₂/C₂H₂ (0.70/0.30/0.03 L·min⁻¹) and respectively observed by scanning electron microscopy (FIG. 10a) and transmission electronic microscopy (FIG. 10b).

FIGS. 11a and 11b are respectively distribution histograms of the external and internal diameters of the nanotubes obtained according to a time mode co-injection synthesis protocol in the presence of a reactive fluid (C₂H₂).

FIGS. 12a, 12b and 12c respectively represent the variations in the residual iron content in the samples (FIG. 12a), catalytic yield (FIG. 12b) and growth speed (FIG. 12c) as a function of the concentration of ferrocene implemented according to a time mode co-injection synthesis protocol, based on the injection of a constant concentration of ferrocene during one single sequence (black dots), and according to an embodiment according to the invention, that is a spatial mode synthesis based on the injection of a variable concentration of ferrocene during two time sequences (white dots).

FIG. 13 represents the change in the overall chemical yield as a function of the concentration of ferrocene injected during the single sequence of the time mode synthesis illustrated in FIGS. 12a to 12c (black dots) and during the second sequence of the embodiment according to the invention illustrated in FIGS. 12a to 12c (white dots).

FIGS. 14a and 14b represent pictures of aligned carbon nanotubes of a carpet obtained according to a time mode synthesis protocol based on the injection of a variable concentration of ferrocene during two time sequences and observed by scanning electron microscopy according to two different magnifications.

FIG. 15 represents a typical spectrum obtained by Raman spectroscopy of a sample of nanotubes obtained according to a time mode synthesis protocol based on the injection of a variable concentration of ferrocene during two time sequences.

FIG. 16 shows the ratios of the intensity of the band D to the intensity of the band G (I_{D}/I_{G}) of the samples obtained according to a time mode synthesis protocol based on the injection of a variable concentration of ferrocene during two time sequences.

FIG. 17 represents a picture observed by TEM of a sample of nanotubes obtained according to a time mode synthesis protocol based on the injection of a variable concentration of ferrocene during two time sequences.

FIGS. 18a and 18b are respectively distribution histograms of the external and internal diameters of the nanotubes obtained according to a time mode synthesis protocol based on the injection of a variable concentration of ferrocene during two time sequences.

FIG. 19 represents the injection profile of the species in the n zones according to a first embodiment of a spatial mode synthesis of a carpet of aligned carbon nanotubes by using the device and the method according to the invention.

FIG. 20 represents the injection profile of the species in the n zones according to a second embodiment of a spatial mode synthesis of a carpet of aligned carbon nanotubes by using the device and the method according to the invention, the injection profile of the species in the n zones being decomposed, for the sake of clarity, into injection profiles in the n zones for each species injected.

FIG. 21 represents the injection profile of the species in the n zones according to a third embodiment of a spatial mode synthesis of a carpet of aligned carbon nanotubes, doped at the middle thereof by nitrogen (presence of NH₃), by using the device and the method according to the invention, the injection profile of the species in the n zones being decomposed, for the sake of clarity, into injection profiles in the n zones for each species injected.

### DETAILED DISCLOSURE OF PARTICULAR EMBODIMENTS

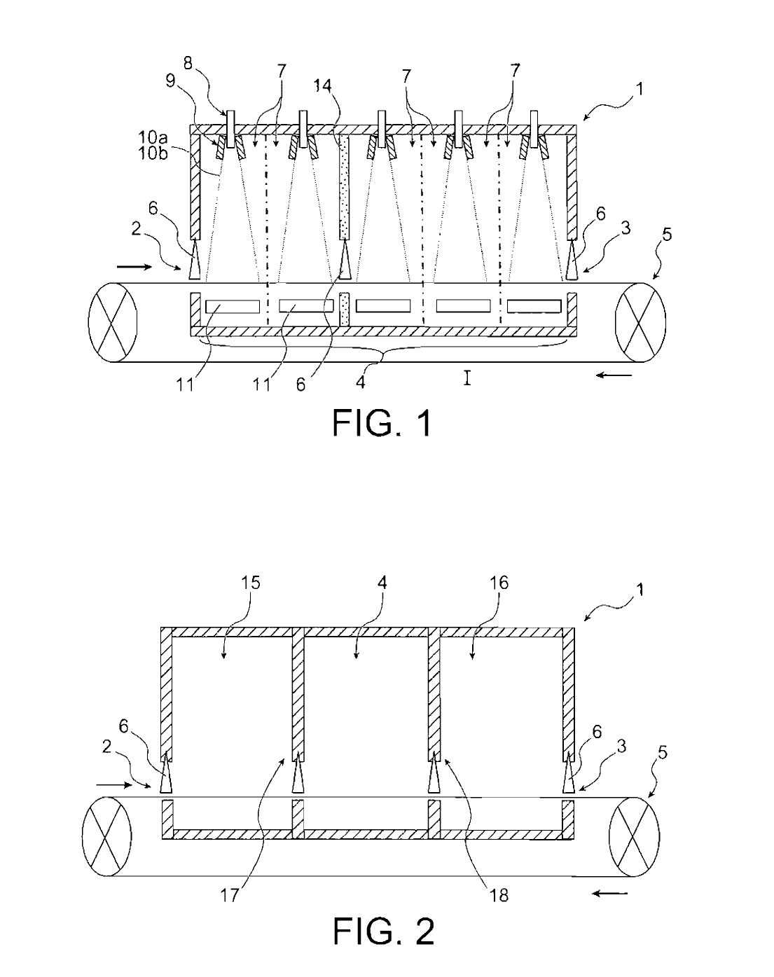

With reference first to FIG. 1, a device according to the invention is represented, formed by an enclosure 1 comprising an inlet 2 and an outlet 3 by which a support (not represented) can enter and exit from the enclosure. Conveying means 5 enable a support to be run in the enclosure.

The enclosure 1 includes a reaction chamber 4, which is formed by the entire inner space of the enclosure, and this reaction chamber is here divided into five distinct zones 7. As set forth above, it is possible that all or part of the zones are separated by a partition wall; in FIG. 1, five zones have been represented, of which two adjacent zones are separated by a partition wall 14 having an aperture provided with containment means 6 (such as, for example, a neutral gas injected as a “curtain gas”) (the space of the other zones not separated by a partition wall being bound by a dashed line).

Each zone is equipped with a first injecting system 8 and possibly a second injecting system (not represented). The first injected system 8 and the second injecting system enable an aerosol flux 10a and a flux of at least one reactive fluid 10b to be respectively injected in their associated zone (the injection cone of the fluxes 10a and 10b being represented by dotted lines), the injections being preferably continuously and simultaneously triggered by control means (not represented) when the support enters this zone.

It is to be noted that for the sake of simplification, only the injectors of the first injecting systems (injector opening into the associated zone) have been represented in FIG. 1.

Each zone is also equipped with a first heating element 11, placed on the bottom part of the zone and intended to heat the support upon passing in this zone, and with a second heating element 9, placed in the top part of the zone and intended to heat the aerosols and fluids injected in the zone. Here, the second heating element 9 is placed directly at the outlet of the first and second injecting systems, so as to heat the aerosols and reactive fluids as soon as they enter in the zone.

Unlike FIG. 1, the device represented in FIG. 2 includes an enclosure having—in addition to a reaction chamber 4—a pre-treatment chamber 15 and a post-treatment chamber 16, respectively located upstream and downstream of the reaction chamber. The pre-treatment chamber 15, the reaction chamber 4 and the post-treatment chamber 16 are separated by partition walls including apertures for passing the support. In FIG. 2, containment means 6 of the curtain gas type have been provided at the outlet 17 of the pre-treatment chamber 15 and the inlet 18 of the post-treatment chamber 16. For the sake of clarity, the n zones of the reaction chamber 4, their first and second heating elements, as well as their first and second injecting systems are not represented.

The conveying means can for example be a conveyor belt. In FIGS. 1 and 2, the conveying means are an endless conveying belt mounted on two parallel rolls at least one of which is rotatably driven.

The first and second heating elements can for example be a resistive heating part (having for example the form of a plate for the first elements and of a cone for the second elements, to fit to the shape of the fluxes injected), radiating heating means (infrared lamps) or an inductive system. In a known manner to those skilled in the art, the temperature in each zone is chosen to be sufficient to activate the growth of the nanostructures; as this minimum temperature depends on the species injected in the zone in question, it is particularly advantageous that each zone has its own heating means.

The control means can include at least one sensor to detect the position of the support with respect to a zone and an actuator which triggers the injection.

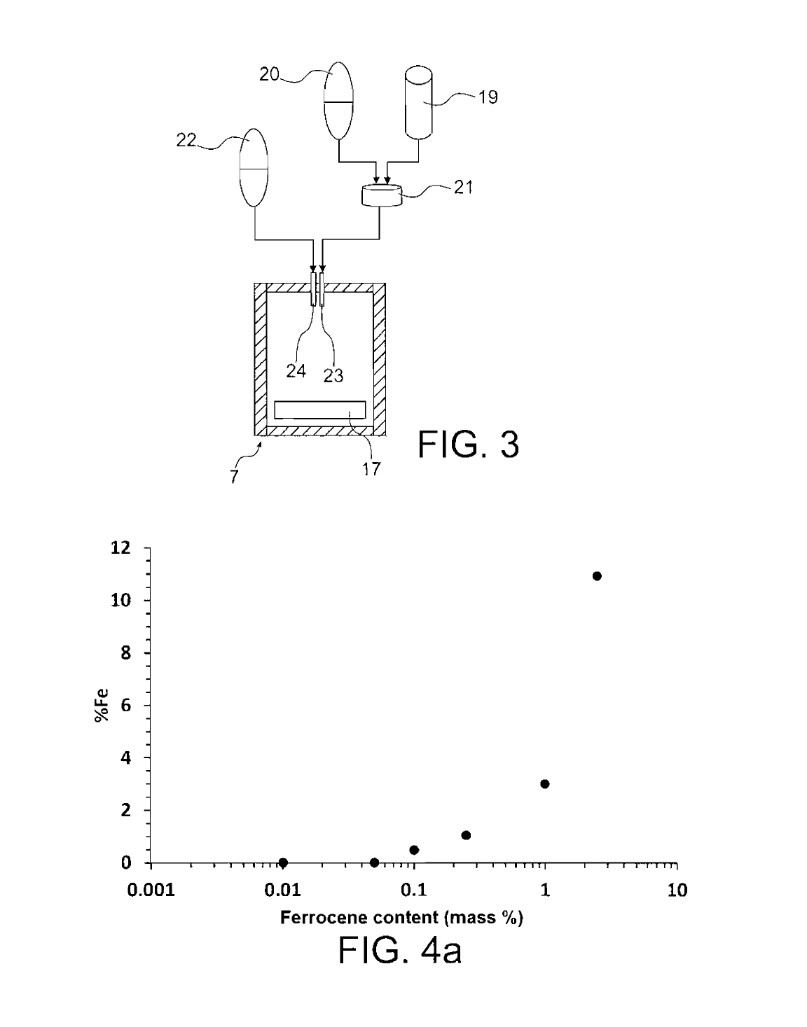

With reference to FIG. 3, which represents a zone 7, an injector 23 of the first injecting system, as well as an injector 24 of the second injecting system, which both open into the top part of the zone 7, can be seen.

In more detail, the first injecting system is comprised of an injector 23, opening into the zone 7, connected to an evaporator 21, in turn connected to a liquid tank 19 and a gas tank 20. The first injecting system is used for injecting an aerosol. To that end, the liquid tank contains a solution comprising a catalytic precursor and a source precursor of the material of the nanostructures to be manufactured, for example a ferrocene and toluene mixture for making carbon nanostructures, and the gas tank 20 contains an inert carrier gas, for example argon. The liquid mixture and the gas join together in the evaporator 21, in which the liquid mixture is sprayed into the carrier gas as droplets to create the aerosol.

The second injecting system enables a flux of one or more reactive fluids to be injected into the zone. The second injecting system includes either, when the fluid is a liquid, a tank containing the liquid, connected to an evaporator, connected to an injector which opens into the associated zone, or, when the fluid is a gas, a tank 22 containing the gas, connected to an injector 24 which opens into the associated zone.

It is to be noted that in FIG. 3, a single injector has been represented per injecting system; however, it is possible that the injecting systems have several injectors, the injection being simultaneously made in each of these injectors.

With the device and the manufacturing method according to the invention, aligned nanostructures on a support can be made. In particular, carbon nanotubes, silicon nanowires, titanium oxide (TiO₂), zinc oxide (ZnO), or tungsten bisulfide WS₂ nanowires can be made.

In the exemplary embodiments that follow, operating modes for manufacturing carpets of aligned carbon nanotubes will be described.

Firstly, the characteristics of the synthesis (yields) and of the nanotubes thus obtained (purity, growth speed, etc.) will be measured to determine the optimum ranges of the synthesis parameters. These measurements will be made from a dense carpet of aligned carbon nanotubes, obtained according to a co-injection synthesis protocol, based on one or more time sequence(s) made on a stationary substrate (examples 1a, 1b and 1c below).

Then, the optimum synthesis protocols by switching from the time mode (stationary substrate) to the spatial mode (running substrate) will be defined (examples 2 to 4). These examples 2 to 4 will be obtained by using the device according to the invention, which is represented in FIG. 1, that is a device in which the enclosure and the reaction chamber are one single element, and in which the reaction chamber is divided into five zones. The five zones are each equipped with a first injecting system and a second injecting system, with a first heating element provided at the bottom of each zone and intended to heat the support, and with a second heating element provided at the outlet of the injectors of the first and second injecting systems and intended to heat the outflow fluxes of both these systems. It is to be noted that the partition wall 14 is optional.

For making carbon nanotubes, various carbon gases can be used as a carbon source (hydrocarbons, alcohols, carbon monoxide, carbon halides, etc.); the carbon source can also be in a liquid (toluene, cyclohexane, vegetal origin oils (camphor, eucalyptus, etc.)) or solid form, and be used in a pure form, when it is in a liquid form, or dissolved in a solvent when it is in a liquid or solid form. This carbon source can also contain heteroatoms such as nitrogen or boron (benzylamine, acetonitrile, etc.).

As a metal precursor, a transition metal metallocene can be used.

The carrier gas can be an inert or reactive gas; it can be for example argon (Ar) or helium (He).

The reactive fluids injected by the second injecting system can be liquid or gaseous; it can be water (H₂O), acetylene (C₂H₂), nitrogen (N₂), ammonia (NH₃), carbon dioxide (CO₂), ethylene (C₂H₄), hydrogen (H₂) or any other heteroatom precursor (boron or phosphorus type, for example).

As a support for growing the nanostructures, there is a large choice of substrates. A planar quartz or silicon substrate or even a planar metal substrate, such as a steel or aluminium substrate can be chosen; porous substrates, such as fibrous fabrics, porous ceramic membranes, metal grids, etc. can also be used. It is to be noted that the choice of the carbon source precursor, the choice of the catalytic precursor and the choice of the reactive fluid have to take the heat resistance temperature of the chosen support into account.

In the description of the operating modes that follow, toluene as a carbon source precursor, ferrocene as a catalytic precursor, argon as a carrier gas, quartz as a support and, optionally, hydrogen or acetylene as a reactive fluid will be used.

The synthesis of aligned carbon nanotubes by CVD is known to those skilled in the art and is not described in detail herein. In the n zones, the CVD synthesis is conventionally made, that is at a temperature between 550 and 1100° C. (preferably between 550 and 850° C.) and at a pressure between 10 mbar and 1 atm for growing carbon nanotubes, preferably at a pressure between 900 mbar and 1 atm.

### Examples 1a, 1b and 1c

### Making and Characterising a Dense Carpet of Aligned Carbon Nanotubes, Obtained According to a Synthesis Protocol Based on One or More Time Sequences (Stationary Substrate)

In this example, a CVD enclosure is used, the reaction chamber of which is a horizontally provided quartz tube in which a stationary substrate is positioned before growing the nanostructures (typically a laboratory device as described in document [7]).

The precursor (catalytic+source) mixture required for growing the nanostructures is sequentially injected over time, each of the sequences being characterised by a different concentration of the catalytic precursor in the case when there are at least two sequences.

Examples 1a, 1 and 1c below will enable characteristics both about synthesis (yields) and nanotubes thus obtained (purity, growth speed, diameters, etc.) to be measured and optimum ranges of synthesis parameters to be determined.

### Example 1a

### Injection of a Constant Concentration of Ferrocene During One Single Sequence

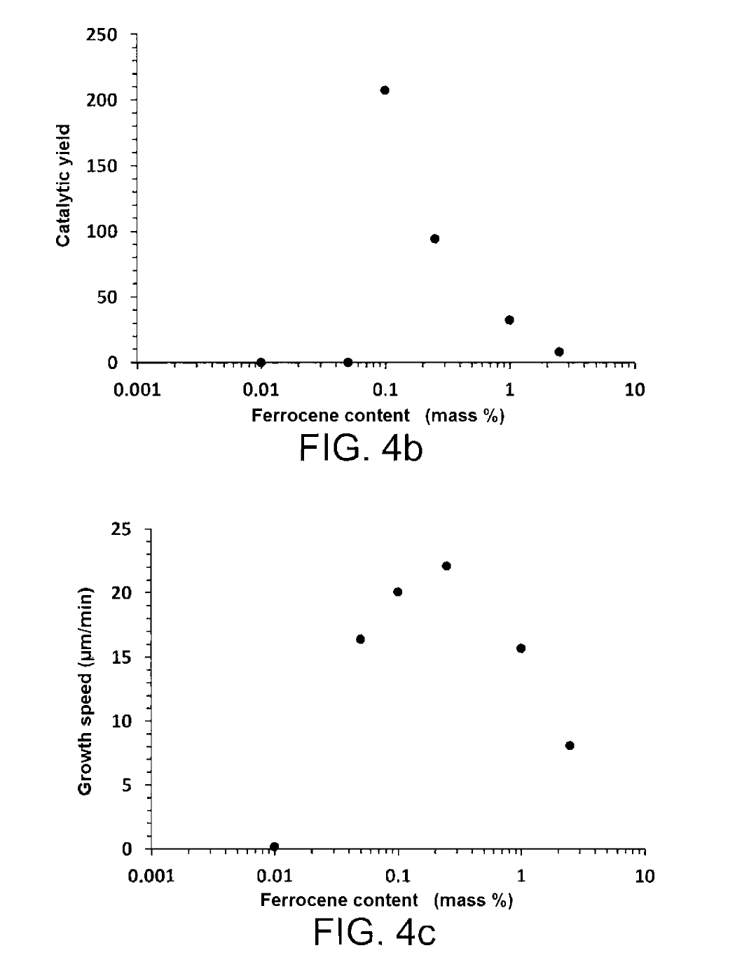

FIGS. 4a to 9b show the results obtained by continuously injecting in a single sequence a constant concentration of ferrocene in the toluene/ferrocene mixture with, in particular, the effect of different concentrations of ferrocene (between 0.01 and 2.5% by weight for the different syntheses, with respectively 0.01, 0.05, 0.1, 0.25, 1, 2.5% by weight for samples 1 to 6) on the characteristics of the method and the nanotubes obtained.

The nanotubes are synthesised at a temperature of 800° C. by using an argon/H₂ mixture (70/30% vol) as a carrier gas, for a time period of 15 minutes.

FIGS. 4a, 4b and 4c respectively represent the variations in the residual iron content in the samples (FIG. 4a), catalytic yield (FIG. 4b) and growth speed (FIG. 4c) as a function of the concentration of ferrocene implemented.

The iron content is measured by thermogravimetric analysis (TGA) under the air: the carbon, making up the nanotubes, is oxidised, thus releasing volatile carbon species, whereas the residual iron is oxidized as powdered Fe₂O₃, the measurement of its mass by TGA enabling its proportion to be calculated in the sample.

The catalytic yield is calculated according to the formula:

R_{catalytic}=(m_{C}/m_{Fe})

m_{C} being the carbon mass in the sample and m_{Fe} being the iron mass in the sample.

The growth speed is obtained by measuring, by scanning electron microscopy, the length of the nanotubes obtained and by dividing this value by the synthesis time period.

FIG. 4a shows that the lower the residual iron content in the samples, the lower the injected ferrocene content is.

On the other hand, the catalytic yield (FIG. 4b) has a non-monotonic change with the concentration of ferrocene and, surprisingly, an extremely high and maximum catalytic yield is obtained for a concentration of ferrocene of 0.1% by weight, whereas beyond this, the yield significantly decreases.

Upon reading FIG. 4c, it is noted that the growth speed significantly increases up to a concentration of ferrocene of 0.25% by weight, and then quickly drops to reach relatively low values (in the order of 8 μm/min for 2.5% by weight of ferrocene).

In conclusion, it is noted that particularly interesting results are obtained for a ferrocene content of 0.1% by weight (very good catalytic yield, high purity and growth speed higher than 20 μm/min).

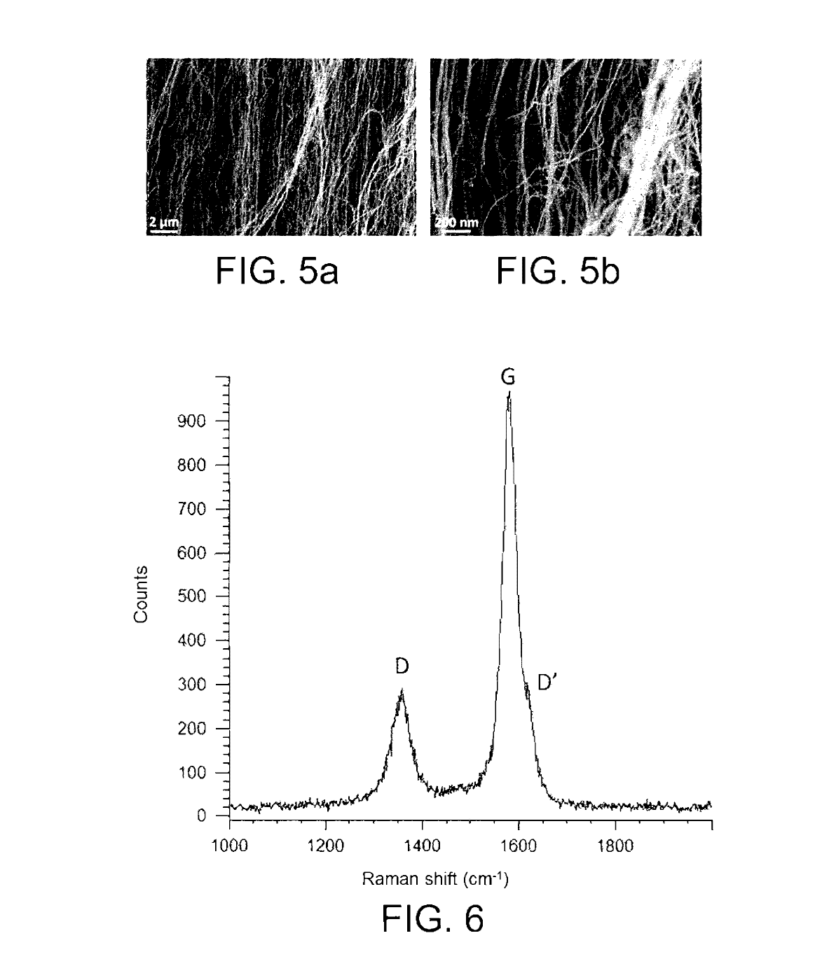

FIGS. 5a and 5b show the typical appearance of the nanotubes observed by SEM (scanning electron microscopy), regardless of the concentration of ferrocene injected for the samples 2 to 5 (0.05% to 1% by weight). It is noted that the carbon nanotubes obtained are aligned and contain a very small amount of impurities (residual catalyst (iron)-based particles, disorganised carbon particles). Indeed, a very small amount of impurities has been observed, except for products obtained from the concentration of ferrocene of 2.5% by weight (sample 6), for which residual catalyst-based particles have been observed. For sample 1 (0.01% by weight), the growth speed of the nanotubes is close to 0 and no picture could be obtained.

In FIG. 6 is shown a typical spectrum obtained by Raman spectroscopy at an incident wavelength of 532 nm and which highlights the presence of the bands G, D and D′, the positions of which are characteristic of carbon nanotubes.

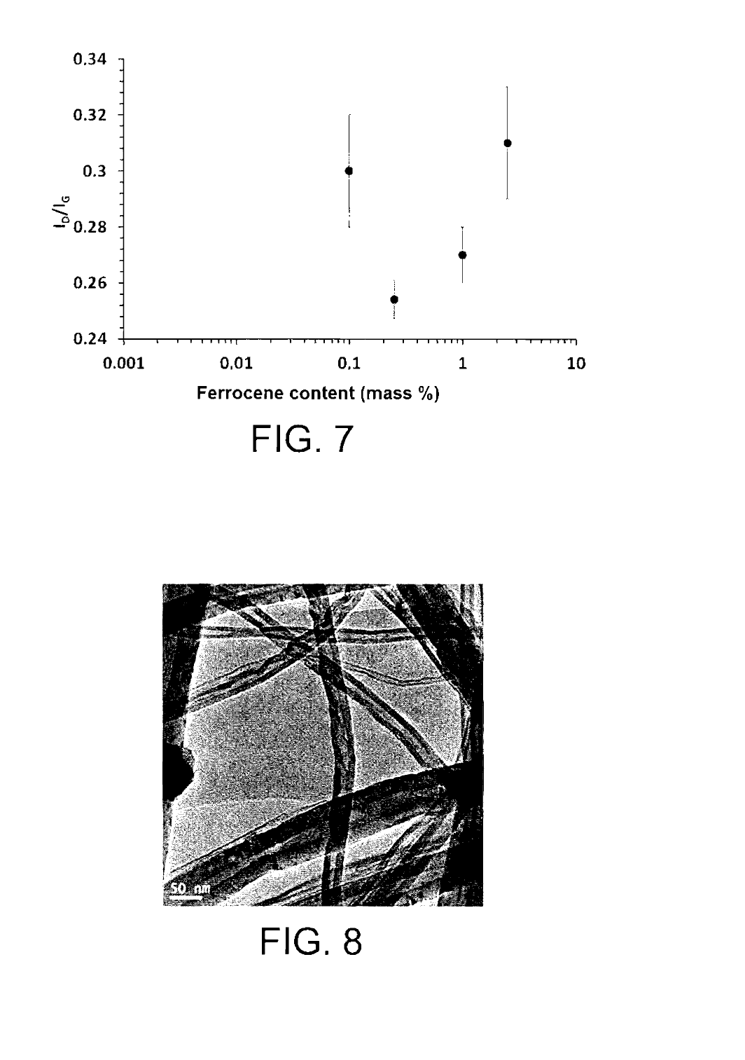

FIG. 7 shows the ratios of the intensity of the band D to the intensity of the band G (I_{D}/I_{G}) of samples 3 to 6. According to the literature, it is admitted that the higher this ratio, the more defective the nanotube structure is. In particular, many multi-sheet nanotubes obtained by CVD have a ratio in the order of 0.8 and 1. For samples 3 to 6, it is noted that the ratio is much lower (in the order of 0.3) and is very hardly modified by the concentration of ferrocene injected, indicating a good structural quality of the nanotubes thus produced.

FIG. 8 represents a picture observed by TEM (transmission electron microscopy) of a nanotube sample highlighting the formation of multi-sheet nanotubes having a very small amount of impurities, which is in particular the case for sample 3 obtained with a concentration of 0.1% by weight of ferrocene. For sample 6 obtained with a concentration of 2.5% by weight of ferrocene, impurities such as residual iron-based particles have been observed.

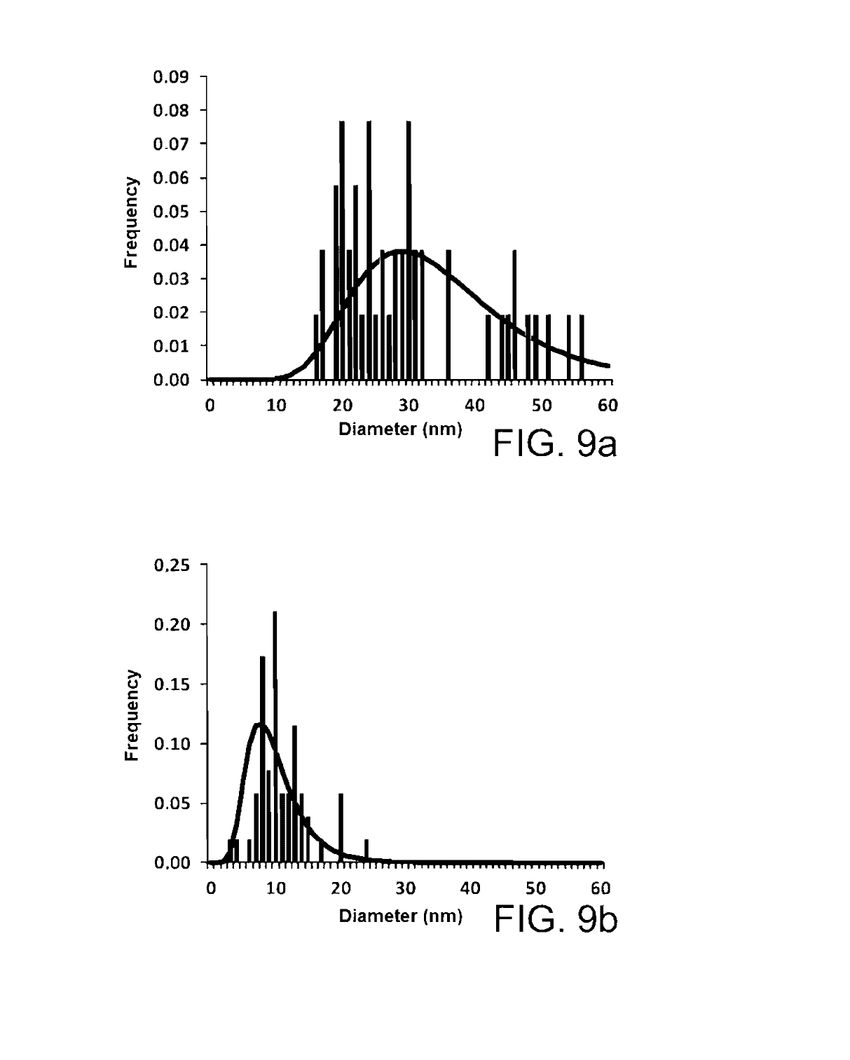

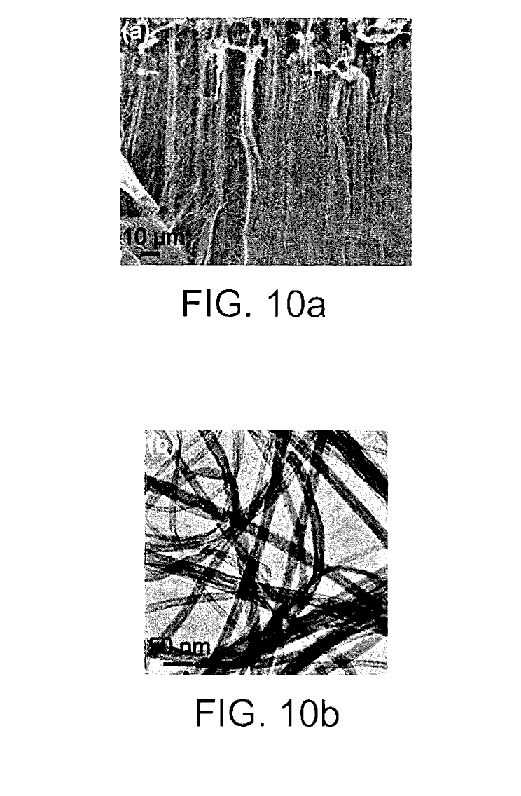

The external and internal diameters measured based on this picture are presented in the histograms in FIGS. 9a and 9b, the average external diameter (FIG. 9a) being in the order of 30 nm and the average internal diameter (FIG. 9b) being in the order of 9 nm. These measurements have also been made for the other samples (except for sample 1), whereby the nanotubes obtained were found to have the same average internal and external diameters regardless of the concentration of ferrocene injected.

### Example 1b

### Injection of a Constant Concentration of Ferrocene During One Single Sequence in the Presence of a Reactive Fluid (Acetylene)

FIGS. 10a-b and 11a-b show the results obtained by continuously injecting in a single sequence a constant concentration of ferrocene in the toluene/ferrocene mixture (10% by weight) with, in particular, the effect of the reactive fluid (acetylene) on the characteristics of the method and the nanotubes obtained.

The nanotubes are synthesised at a temperature of 800° C. by using a gaseous mixture Ar/H₂/C₂H₂ (0.70/0.30/0.03 L·min⁻¹) with Ar as a carrier gas and H₂/C₂H₂ as a reactive fluid, for a time period of 15 minutes.

FIG. 10a illustrates the morphology of the nanotubes observed by SEM scanning electron microscopy) at the surface of the quartz support. It is observed that carbon nanotubes obtained are aligned, long, and contain a very small amount of impurities (residual catalyst (iron)-based particles), disorganised carbon particles).

The growth speed is obtained by measuring, by scanning electron microscopy, the length of the nanotubes obtained and by dividing this value by the synthesis time period. Upon reading FIG. 10a, it is noted that the growth speed reaches 16.6 μm/min in the presence of acetylene, that is a value markedly higher than that reported in FIG. 4c for a high concentration of ferrocene, but in the absence of acetylene.

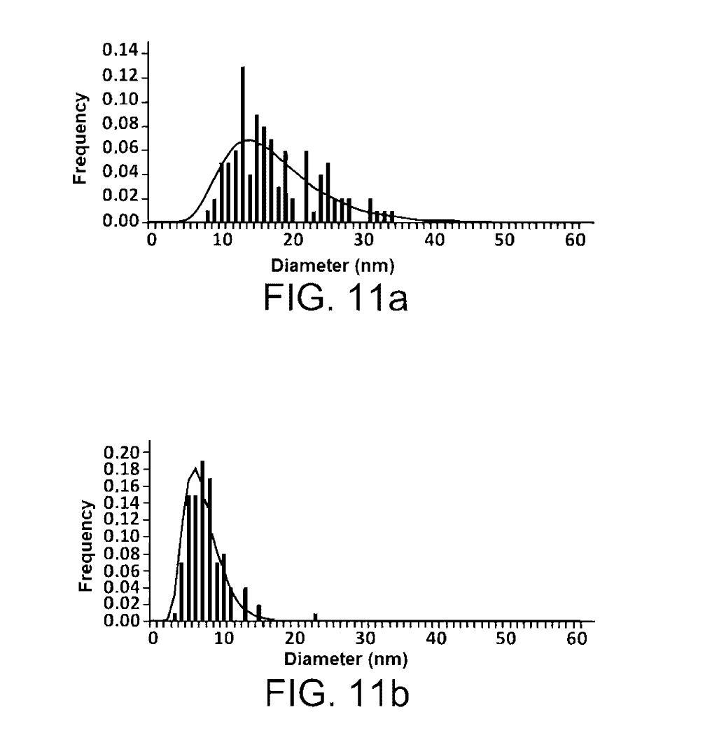

FIG. 10b represents a picture observed by TEM (transmission electron microscopy) of these nanotubes highlighting the formation of multi-sheet carbon nanotubes having a small amount of impurities in the centre core or outside the nanotubes; only impurities such as residual iron-based particles have been observed. The external diameters measured based on these TEM pictures are presented in the histograms of FIGS. 11a and 11b. The average external diameter (FIG. 11a) is in the order of 18 nm, that is substantially lower than the average external diameter obtained in the absence of the reactive fluid, and the average internal diameter (FIG. 11b) is in the order of 7 nm. The residual iron content measured by TGA is 3.9% by weight.

### Example 1c

### Injection of a Variable Concentration of Ferrocene During Two Time Sequences

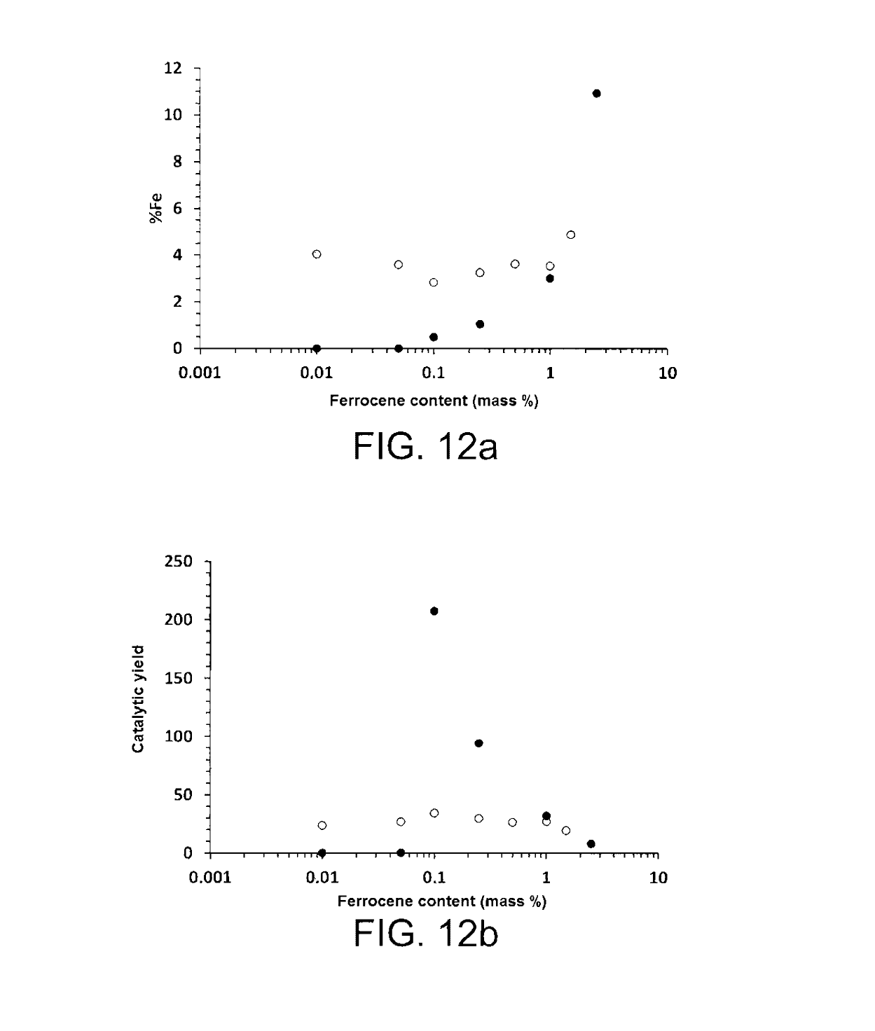

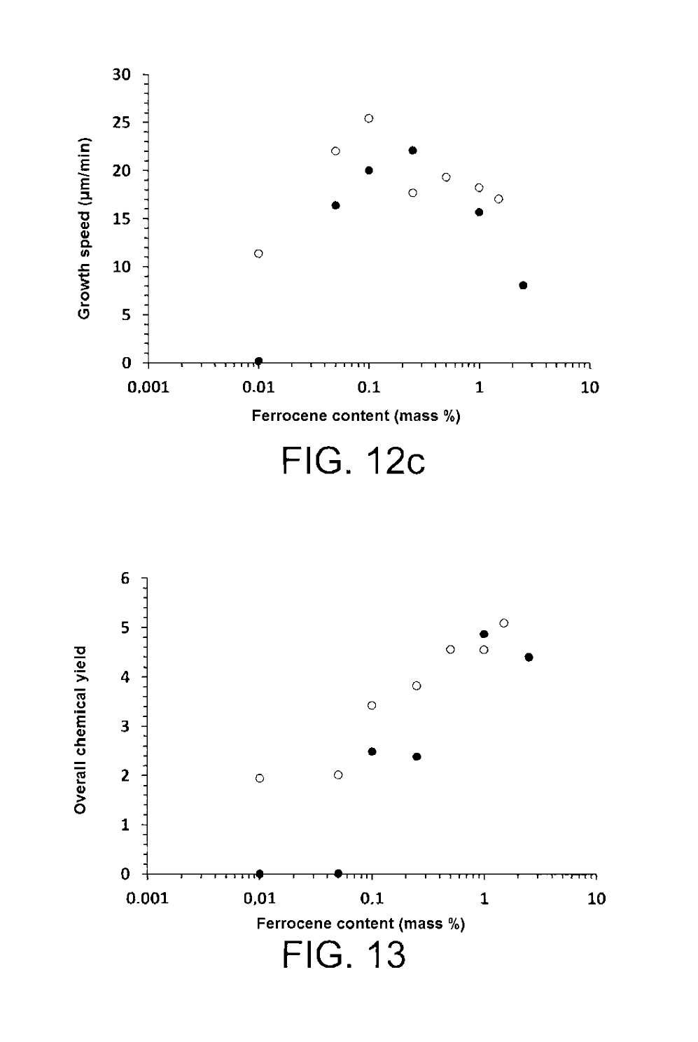

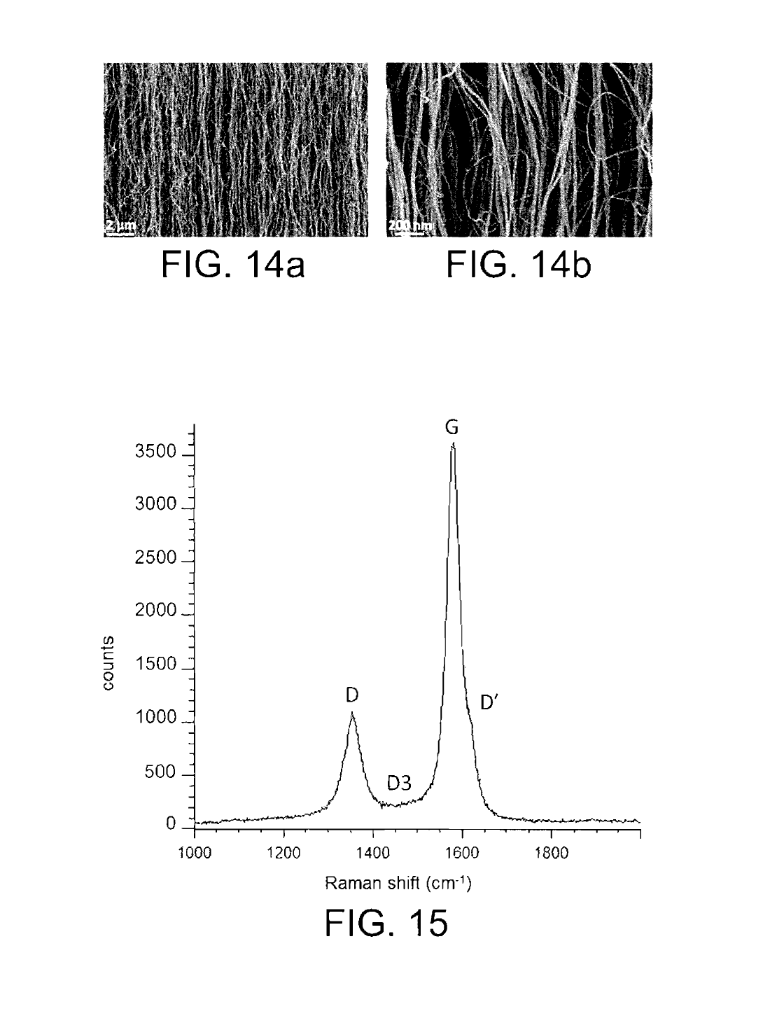

White dots in FIGS. 12a-c, 13, 16 and FIGS. 14a-b, 15, 17, 18a-b show results obtained by injecting, during the first sequence, a solution containing 2.5% by weight of ferrocene in the toluene/ferrocene mixture, the synthesis time period being 1 min 40, and by injecting, during a second sequence, a solution containing a lower concentration of ferrocene, which is varied in the range [0.01-1.25]% by weight for the different syntheses (respectively 0.01, 0.05, 0.1, 0.25, 0.5, 1, 1.5% by weight for samples a to g), the synthesis time period being 13 min 20.

The effect of the different concentrations of ferrocene injected in the second sequence on the characteristics of the method and the nanotubes obtained are presented in the figures that follow.

For both sequences, the growth temperature is set to 800° C. and the carrier gas is an argon/H₂ mixture (70/30% vol), the cumulative synthesis time period on both sequences being 15 minutes.

By way of comparison, the results obtained in example 1a by injecting a constant concentration of ferrocene during a single sequence are also shown (represented by black dots).

FIGS. 12a, 12b and 12c respectively represent the variations in residual iron content in the samples (FIG. 12a), catalytic yield (FIG. 12b) and growth speed (FIG. 12c) as a function of the concentration of ferrocene implemented during the second sequence (white dots) or during a single sequence (black dots).

The iron content is measured by a thermogravimetric analysis (TGA) under the air.

The catalytic yield is calculated as explained above.

FIG. 12a shows that the residual iron content in samples a to g is low and is around 4% by weight with however a minimum at 2.8% by weight for a concentration of ferrocene injected during the second sequence of 0.1% by weight of ferrocene.

FIG. 12b in turn shows that the catalytic yield remains between 20 and 35, with an optimum at 35 for a concentration of ferrocene of 0.1% by weight injected during the second sequence. In comparison with an injection of a low and constant concentration of ferrocene during one single sequence (black dots), the injection of different concentrations according to two successive sequences results in a decreased catalytic yield and to an increased residual iron content, remaining however in a proper content range in terms of product purity.

FIG. 12c shows the change in the growth speed as a function of the concentration of ferrocene injected during the second sequence or in one single sequence. The growth speed is obtained according to the method described above in the example 1a.

It is noted that the growth speed increases when the injected ferrocene content during the second sequence increases up to a content of 0.1% by weight, and then decreases. This change is identical to that measured in the case of an injection of a constant concentration in one single sequence (example 1a), even if, in the example 1a, the maximum of the growth speed is at 0.25% by weight of ferrocene. However, the growth speed remains higher overall in the case when the concentration of ferrocene varies according to the sequences (example 1c).

FIG. 13 represents the change in the overall chemical yield as a function of the concentration of ferrocene injected during the second sequence (white dots) or during one single sequence (black dots).

The overall chemical yield (expressed in %) is the result of the ratio of the total mass of the product obtained to the total mass of the precursor injected, multiplied by 100.

It is noted that the overall chemical yield increases when the concentration of ferrocene increases during the second sequence and remains always higher overall in comparison with an injection of a constant concentration of ferrocene during one single sequence.

FIGS. 14a and 14b show the typical appearance of the nanotubes observed by SEM, regardless of the concentration of ferrocene injected during the second sequence for samples a to g (0.01% to 1.5% by weight). It is noted that the carbon nanotubes obtained are aligned and contain a very small amount of impurities (residual catalyst (iron)-based particles, disorganized carbon particles). Indeed, a very small amount of impurities could be observed in samples a to g.

In FIG. 15 is shown a typical spectrum obtained by Raman spectroscopy at an incident wavelength of 532 nm and which highlights the presence of the bands G, D and D′, the positions of which are characteristic of carbon nanotubes.

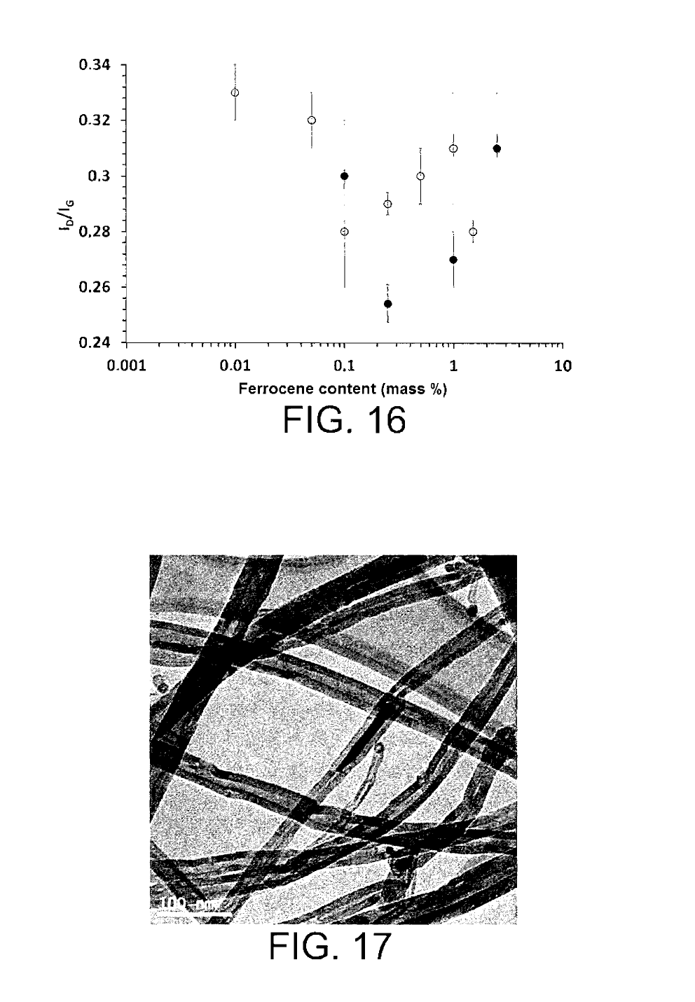

FIG. 16 shows the ratios of the intensity of the band D to the intensity of the band G (I_{D}/I_{G}) of samples a to g (white dots) and, for comparison, the ratios obtained in example 1a for samples 3 to 6 (black dots) have also been introduced. It is noted that, for samples a to g, a ratio in the order of 0.3 is obtained, which indicates a good structural quality of the nanotubes produced. This ratio decreases when the concentration of ferrocene injected during the second sequence increases up to 0.1% by weight, and then increases again when the concentration of ferrocene increases.

If the ratios obtained in example 1a (constant concentration of ferrocene injected in one single sequence) are compared to example 1c (variable concentration of ferrocene injected according to two sequences), it is noted that the ratio remains overall in the same order of magnitude regardless of the way of injecting ferrocene.

FIG. 17 represents a picture observed by TEM of a sample of nanotubes highlighting the formation of multi-sheet nanotubes having a very small amount of impurities, which is the case in particular for sample c obtained with a concentration of ferrocene of 0.1% by weight.

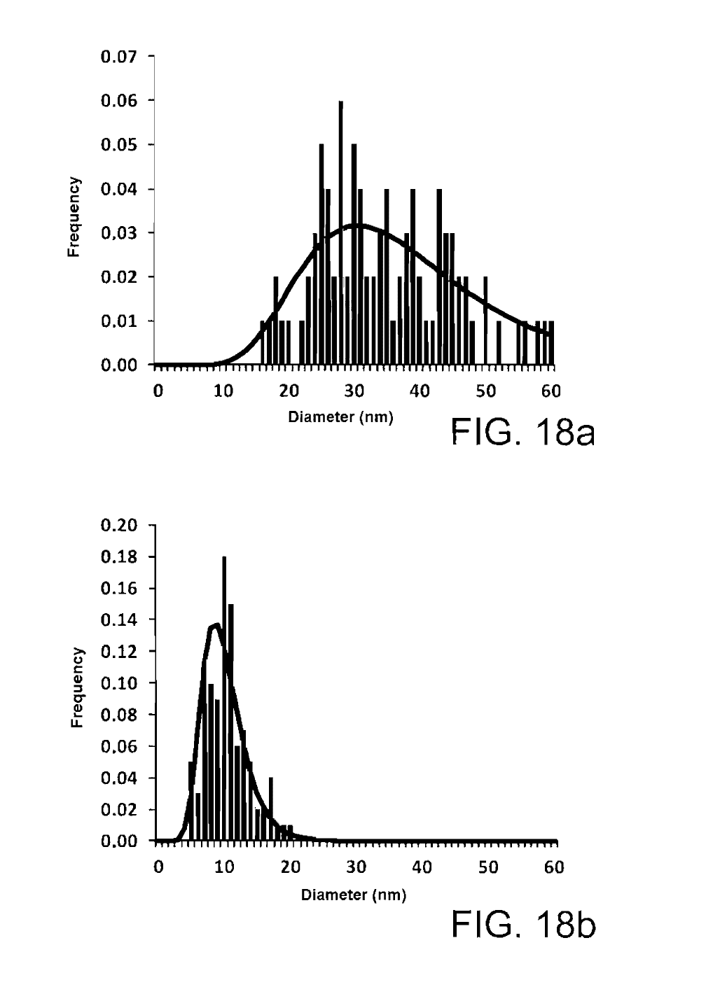

The external and internal diameters measured based on this picture are presented in the histograms in FIGS. 18a and 18b, the average external diameter (FIG. 18a) being in the order of 30 nm and the average internal diameter (FIG. 18b) being in the order of 9 nm. These measurements have also been made for the other samples, whereby the nanotubes obtained were found to have the same average internal and external diameters regardless of the concentration of ferrocene injected during the second sequence.

From these examples 1a, 1b and 1c and based on scientific observations regarding the effects of the concentration of ferrocene injected over time according to a mode in a single sequence (constant concentration of ferrocene over time) or in several successive sequences (variable concentration of ferrocene over time), the inventors have developed new synthesis protocols by transposing these time sequences into spatial sequences. One of the advantages of the device and method according to the invention is that, as a function of what it is desired in terms of production (high overall chemical yield and growth speed or high catalytic yield), it is possible to adjust the implementation of the method by varying the spatial injection profile of the precursors according to the n zones of the device.

### Example 2

### Operating Mode for Making a Carpet of Aligned Carbon Nanotubes According to a Spatial Mode Sequential Synthesis Having an Injection Profile of the Species in the n Zones with Two Different Injection Sequences (Running Substrate)

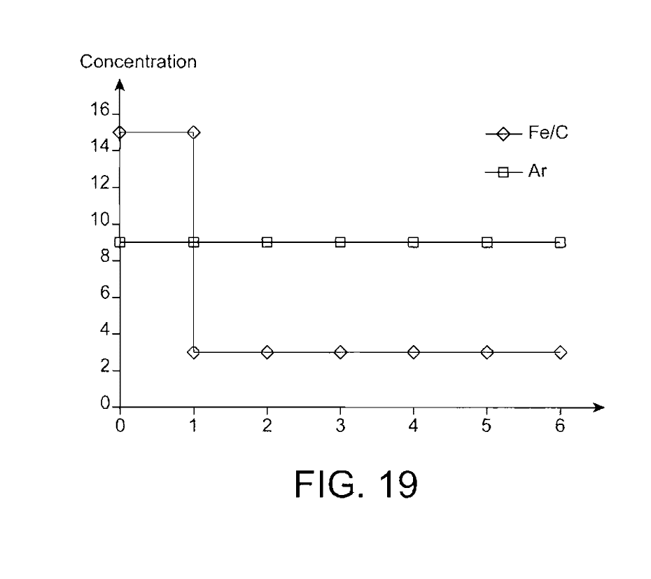

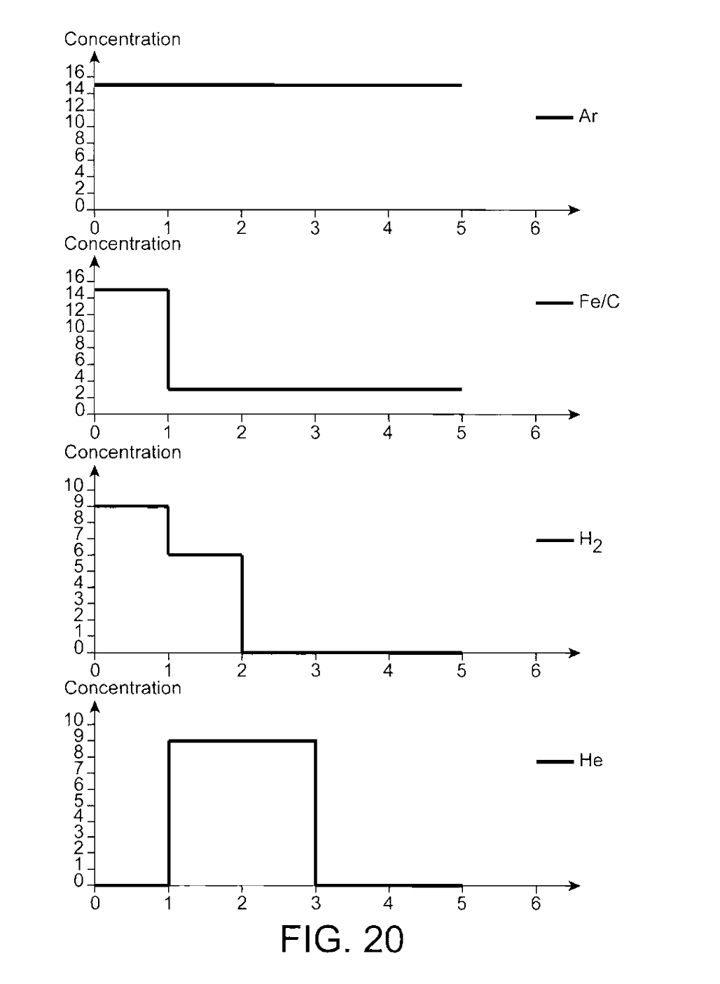

According to the principle of the invention, the support passes through n zones in which local growth conditions prevail, at least two of these n zones having growth conditions which differ at least in the concentration of the catalytic precursor present in the aerosol which is injected. More particularly, FIG. 19 represents an injection profile of the species in the n zones according to a preferred embodiment of the invention, where an aerosol comprising a high concentration of ferrocene is injected in the first synthesis zone (first injection sequence), and then this concentration is strongly decreased in the following zones (second sequence).

In FIG. 19, the injection profile of the species in the n zones includes two injection sequences; to render this injection profile, a CVD device, the reaction chamber of which includes at least two zones having different local growth conditions, has to be used. In our example, the first injection sequence will be made in the first zone and the second injection sequence will occur in the four other zones.

As previously said, the choice of the dimension of the zones in the conveying direction depends on the travelling speed of the conveying means, as well as the injection time period of an injection sequence. It is also possible, instead of using a single zone for an injection sequence, to use several of them, each of these zones consequently having the same local growth conditions.

During the time period of the first injection sequence, a toluene solution comprising ferrocene is injected at a concentration of at least 2.5% by weight, which enables the diameter of the nanoparticles to be decreased and the density of the nanoparticles which act as a seed for the nanotubes to be increased in comparison with a low concentration (≦0.5% by weight), in order to obtain a carpet of nanotubes having a thinner thickness and being denser.

For the second injection sequence, it is injected a toluene solution comprising ferrocene and in which the concentration of ferrocene is lower than in the first injection (the concentration of ferrocene in the solution being lower than or equal to 1% mass, preferably lower than or equal to 0.5%, preferentially lower than or equal to 0.25%). This drastic decrease in the concentration of ferrocene enables the iron residual presence at the heart of the nanotubes (FIG. 12a) to be decreased. This choice also results in increasing the overall chemical yield for the synthesis of the nanotubes (FIG. 13).

The compounds and the relative amounts injected in the five zones are summarised in table 1 below. It is to be noted that the accurate values to be injected are not indicated, because they have to be adjusted as a function of numerous factors, such as the size of the substrates and their specific areas, the size of the n zones, the running speed of the support and the characteristics of the carpet desired to be obtained.

TABLE 1

| Sequence 1 | Sequence 2 | | | |
|---|---|---|---|---|
| (0-1) | (1-5) | | | |
| Zone 1 | Zone 2 | Zone 3 | Zone 4 | Zone 5 |
| [Ferrocene] | [Ferrocene] | [Ferrocene] | [Ferrocene] | [Ferrocene] |
| (high %) | (low %) | (low %) | (low %) | (low %) |
| [Ar] | [Ar] | [Ar] | [Ar] | [Ar] |

In this exemplary operating mode, it has been chosen to have five zones with the same dimensions.

With reference to FIG. 19, the first sequence corresponds to the time laps 0-1 on the time scale and corresponds to the time spent by the support in zone 1 (typically from 1 to 2 minutes); the time lapses 1-2, 2-3, 3-4, 4-5 respectively correspond to the times spent by the support in zones 2, 3, 4, 5, the same species and with identical quantities being injected in the 2^{nd} to 5^{th} zones, which correspond to the second sequence (time lapses 1-5).

### Example 3

### Operating Mode for Making a Carpet of Aligned Carbon Nanotubes According to a Spatial Mode Sequential Synthesis with Three Different Injection Sequences (Running Substrate)

In this synthesis, different carrier gases are involved during the synthesis, that is argon and helium, which will enable the development of carpets of nanotubes having a greater density of nanotubes and nanotubes having smaller diameters with respect to the preceding synthesis to be promoted.

In this exemplary synthesis, the possibility of injecting a reactive fluid (herein dihydrogen) is also illustrated. It has been chosen here to use dihydrogen, but acetylene could have been chosen to be injected, for example.

This sequential synthesis includes three injection sequences; the reaction chamber should thus have at least three zones. As in the previous example, a CVD enclosure, the reaction chamber of which is divided into five zones, as illustrated in FIG. 1, can thus be used.

The compounds and amounts injected in the five zones are summarised in table 2 hereinafter.

TABLE 2

| Sequence 1 | Sequence 2 | Sequence 3 | | |
|---|---|---|---|---|
| (0-1) | (1-2) | (2-5) | | |
| Zone 1 | Zone 2 | Zone 3 | Zone 4 | Zone 5 |
| [Ferrocene] | [Ferrocene] | [Ferrocene] | [Ferrocene] | [Ferrocene] |
| (high %) | (low %) | (low %) | (low %) | (low %) |
| [Ar] | [Ar] | [Ar] | [Ar] | [Ar] |
| [H₂] (high %) | [H₂] (low %) | | | |
| | [He] | | | |

With reference to FIG. 20, it can be seen that, throughout the first injection sequence, a toluene and ferrocene solution is injected, the concentration of ferrocene being higher than or equal to 10% by weight in a dihydrogen concentrated reaction atmosphere (typically a volume percentage between 5 and 60%). This dihydrogen injection results in decreasing the ferrocene decomposition temperature and, consequently, the nanotube synthesis temperature.

In the second injection sequence, a solution having a low concentration of ferrocene is injected, the concentration of ferrocene in the solution being lower than or equal to 1% by weight, preferably lower than or equal to 0.5% by weight, preferentially lower than or equal to 0.25% by weight. Further, a smaller amount of dihydrogen with respect to the preceding sequence is injected and another neutral gas is injected, as for example helium (or extra argon). This results in also varying the nanotube synthesis temperature, because of the heat capacities of the gases employed.

In the third injection sequence, a solution having a low concentration of ferrocene is injected in a standard all-argon atmosphere, which enables to come back to the initial synthesis conditions.

### Example 4

### Operating Mode for Making a Dense Carpet of Aligned Doped Carbon Nanotubes According to a Spatial Mode Sequential Synthesis with Five Different Injection Sequences (Running Substrate)

In this synthesis, in addition to the species injected in example 3, a small amount of water and a precursor including a heteroatom such as nitrogen, for example ammonia water volume percentage between 0.0001% and 0.1% and ammonia volume percentage between 0.001% and 60%) is further injected in order to make a carpet of doped aligned nanotubes on all or part of their height and in which the carpet of nanotubes is more easily peeled off than if no water would be injected. It is to be noted that this exemplary synthesis is for illustrative purposes and in particular, there is no correlation between water (as steam) and ammonia injection.

The compounds and the amounts injected in the five zones are summarised in table 3 below.

TABLE 3

| Sequence 1 | Sequence 2 | Sequence 3 | Sequence 4 | Sequence 5 |
|---|---|---|---|---|
| (0-1) | (1-2) | (2-3) | (3-4) | (4-5) |
| Zone 1 | Zone 2 | Zone 3 | Zone 4 | Zone 5 |
| [Ferrocene] | [Ferrocene] | [Ferrocene] | [Ferrocene] | [Ferrocene] |
| (high %) | (low %) | (low %) | (low %) | (low %) |
| [Ar] | [Ar] | [Ar] | [Ar] | [Ar] |
| [H₂] (high %) | [H₂] (low %) | [He] | [NH₃] | [H₂O] |
| [H₂O] | [He] | [NH₃] | | |

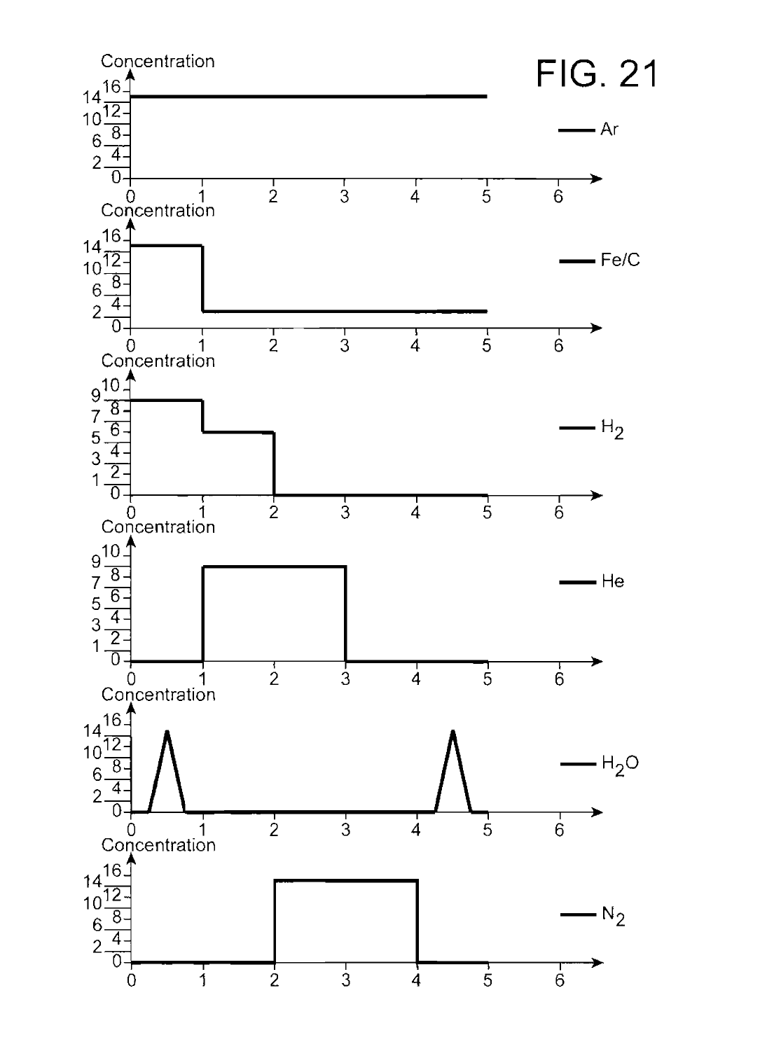

With reference to FIG. 21, it can be seen that, throughout the first injection sequence (which occurs in zone 1), a toluene and ferrocene solution, the concentration of ferrocene of which is high in a dihydrogen concentrated reaction atmosphere, is injected. A small amount of water is also injected (the injection being pulsed).

In the second injection sequence, a solution having a low concentration of ferrocene, argon, a lower amount of dihydrogen with respect to the first sequence, as well as helium (or extra argon) are injected.

In the third injection sequence, a solution having the same concentration of ferrocene as in the second sequence and the same amounts of argon and helium as in the second sequence is injected. A small amount of ammonia is further injected, which results in inserting a nitrogen heteroatom as a dopant in the nanotubes, thus making a carpet of doped nanotubes in the middle thereof.

In the fourth injection sequence, a solution having the same concentration of ferrocene as in the third sequence in a standard all-argon atmosphere is injected and, as in the third sequence, a small amount of ammonia is further injected.

Finally, in the fifth injection sequence, a solution having the same concentration of ferrocene as in the fourth sequence in a standard all-argon atmosphere is injected and a small amount of water (the injection being pulsed) is further injected, by stopping the ammonia injection to come back to non-doped nanotubes.

### Example 5

### Operating Mode for Making a Carpet of Aligned Carbon Nanotubes According to a Spatial Mode Sequential Synthesis with Five Different Injection Sequences (Running Substrate) in the Presence of a Carbon Reactive Fluid

For this synthesis, the series of sequences presented in table 4 allows for a variation, in at least two of the n zones, of at least one of the following parameters: the chemical composition of the carrier gas, the mass concentration of the catalytic precursor in the precursor mixture. In addition to the species injected in example 3, a carbon reactive fluid such as acetylene will be further injected, the latter having the advantage to decompose as soon as 600° C., thus enabling to operate at a lower temperature.

The compounds and the amounts injected in the five zones are summarized in table 4 below.

TABLE 4

| Sequence 1 | Sequence 2 | | | |
|---|---|---|---|---|
| (0-1) | (1-5) | | | |
| Zone 1 | Zone 2 | Zone 3 | Zone 4 | Zone 5 |
| [Ferrocene] | [Ferrocene] | [Ferrocene] | [Ferrocene] | [Ferrocene] |
| (high %) | (low %) | (low %) | (low %) | (low %) |
| [Ar]/[H₂]/ | [Ar]/[H₂]/ | [Ar]/[H₂]/ | [Ar]/[H₂]/ | [Ar]/[H₂]/ |
| [C₂H₂] | [C₂H₂] | [C₂H₂] | [C₂H₂] | [C₂H₂] |

Throughout the first injection sequence which occurs in zone 1), a toluene and ferrocene solution the concentration of ferrocene of which is high (for example 10% by weight) is injected, in the presence of a gas mixture Ar/H₂/C₂H₂, with Ar as a carrier gas and H₂/C₂H₂ as a reactive fluid. The mixture proportions of the gases are 3.5/1.5/0.25 L·min⁻¹ and the mixture flow rate is constant (it is here of about 5 L·min⁻¹). In the second sequence (which occurs in zones 2 to 5), a toluene solution having a low concentration of ferrocene (for example 1.25% by weight) is injected, still in the presence of the gas mixture Ar/H₂/C₂H₂ (proportions and flow rate unchanged with respect to the first sequence), which results in decreasing the diameter of the nanotubes and enable them to be grown at a lower temperature.

It is to be noted that in examples 2 to 5 above, the injections are continuous, except for the water injection, in example 4, which is pulsed.

The different preceding examples highlight the richness of the operating modes that can be implemented with the device with n zones according to the invention for continuously making aligned nanostructures.

In examples 2 to 5, it has been chosen to make the injection operations by modifying, in at least two of the n zones, at least the mass concentration of the catalytic precursor in the catalytic precursor and source precursor mixture. But it is quite possible to choose to modify, at the very least, the flow rate of the carrier gas flux or the chemical composition of the carrier gas.

By way of example, the compounds and the amounts injected in a device according to the invention comprising five zones in order to make a synthesis having an injection profile with two injection sequences have been summarised in tables 5 and 6 below, where only the flow rate of the carrier gas flux (table 5) is modified and where only the chemical composition of the carrier gas (table 6) is modified.

In table 5 hereinafter, the concentration of ferrocene is constant and is for example lower than 0.5% by weight; the carrier gas used is argon and its flow rate is in the order of 5 L·min⁻¹ in the first sequence and in the order of 1 L·min⁻¹ in the second sequence.

TABLE 5

| Sequence 1 | Sequence 2 | | | |
|---|---|---|---|---|
| (0-1) | (1-5) | | | |
| Zone 1 | Zone 2 | Zone 3 | Zone 4 | Zone 5 |
| [Ferrocene] | [Ferrocene] | [Ferrocene] | [Ferrocene] | [Ferrocene] |
| (low %) | (low %) | (low %) | (low %) | (low %) |
| [Ar] | [Ar] | [Ar] | [Ar] | [Ar] |
| (high flow | (low flow | (low flow | (low flow | (low flow |
| rate) | rate) | rate) | rate) | rate) |

In table 6 below, the concentration of ferrocene is constant and is for example lower than 0.5%; in the first sequence, the carrier gas used is helium, which results in decreasing the diameter of the nanotubes, whereas in the second sequence, the chemical composition of the carrier gas is a helium and argon mixture with the proportion 70/30% by volume. This results in also varying the nanotube synthesis temperature, because of the heat capacities of the gases employed. In both sequences, the carrier gas flow rate is constant and is for example in the order of 5 L·min⁻¹.

TABLE 6

| Sequence 1 | Sequence 2 | | | |
|---|---|---|---|---|
| (0-1) | (1-5) | | | |
| Zone 1 | Zone 2 | Zone 3 | Zone 4 | Zone 5 |
| [Ferrocene] | [Ferrocene] | [Ferrocene] | [Ferrocene] | [Ferrocene] |
| (low %) | (low %) | (low %) | (low %) | (low %) |
| [He] | [He]/[Ar] | [He]/[Ar] | [He]/[Ar] | [He]/[Ar] |

### REFERENCES CITED

[1] US 2010/0260933 A1
[2] US 2013/0045157 A1
[3] US 2009/0053115 A1
[4] C. Castro et al., “The role of hydrogen in the aerosol-assisted chemical vapour deposition process in producing thin and densely packed vertically aligned carbon nanotubes” CARBON 61 (2013), pages 585-594
[5] M. Pinault et al, “Evidence of sequential lift in growth of aligned multi-walled carbon nanotube multilayers”, Nano Letters (2005), 5(12), pages 2394-2398
[6] FR 2 927 619 A1
[7] C. Castro et al., “Dynamics of catalyst particle formation and multi-walled carbon nanotube growth in aerosol-assisted catalytic chemical vapour deposition”, CARBON 48 (2010), pages 3807-3816

1: A method for continuously manufacturing aligned nanostructures on a running support, the method comprising
conveying the support through a heated space in a conveying direction, and
synthesising, in this space, the aligned nanostructures on the support by catalytic chemical vapour deposition,
wherein
the heated space is divided into n consecutive zones in the conveying direction of the support, n being an integer higher than or equal to 2,
the synthesis of the nanostructures results from heating operations and injection operations, in each of the n zones, of a flux of an aerosol containing a mixture of a catalytic precursor and a source precursor of a material of the nanostructures to be formed, conveyed by a carrier gas, and
the injection operations are made by modifying, in at least two of the n zones, at least one parameter selected from the group consisting of a flow rate of the carrier gas flux, a chemical composition of the carrier gas, and a mass concentration of the catalytic precursor in the catalytic precursor and source precursor mixture.

2: The manufacturing method according to claim 1, wherein the catalytic precursor injected in the n zones has a constant mass concentration in the catalytic precursor and source precursor mixture.

3: The manufacturing method according to claim 1, wherein the catalytic precursor injected has, in at least one of the n zones, a mass concentration in the catalytic precursor and source precursor mixture of higher than or equal to 0.01% by weight and lower than or equal to 1% by weight.

4: The manufacturing method according to claim 3, wherein the catalytic precursor injected in said at least one of the n zones has a mass concentration in the catalytic precursor and source precursor mixture of higher than or equal to 0.05% by weight and lower than or equal to 0.5% by weight.

5: The manufacturing method according to claim 1, wherein, assuming a centre of the n zones of the heated space, a total mass concentration of the catalytic precursor present in the catalytic precursor and source precursor mixture injected as an aerosol in the zone or all of the zones located upstream of a centre along the conveying direction is at least twice higher than a total mass concentration of the catalytic precursor present in the catalytic precursor and source precursor mixture injected as an aerosol in the zone or all the zones located downstream of the centre along the conveying direction.

6: The manufacturing method according to claim 1, wherein a mass concentration of the catalytic precursor in the catalytic precursor and source precursor mixture injected as an aerosol in a high concentration zone, which is one of the n zones, is at least twice higher than the mass concentration of the catalytic precursor in the catalytic precursor and source precursor mixture injected as an aerosol in each of the remaining n−1 zones.

7: The manufacturing method according to claim 6, wherein the high concentration zone is the first zone along the conveying direction.

8: The manufacturing method according to claim 6, wherein the mass concentration of the catalytic precursor present in the catalytic precursor and source precursor mixture injected as an aerosol in the high concentration zone is between 2% by weight and a saturation limit of the catalytic precursor in the source precursor and the mass concentration of the catalytic precursor present the catalytic precursor and source precursor mixture injected as an aerosol in the remaining n−1 zones is lower than or equal to 1% by weight.

9: The manufacturing method according to claim 8, wherein the mass concentration of the catalytic precursor present n the aerosol which is injected in the high concentration zone is between 2.5 and 10% by weight and the mass concentration of the catalytic precursor present in the aerosol which is injected in the other n−1 zones is lower than or equal to 0.1% by weight.

10: The manufacturing method according to claim 1, wherein the nanostructures are of carbon, the catalytic precursor is a transition metal metallocene and the source precursor is a hydrocarbon.

11: The manufacturing method according to claim 10, wherein the catalytic precursor is ferrocene and the source precursor is toluene.

12: The manufacturing method according to claim 1,
wherein the injection operations are further carried out by modifying, in at least two of the n zones, an injection flow rate of the catalytic precursor and source precursor mixture.

13: The manufacturing method according to claim 1, wherein the heating operations are carried out at a different temperature in at least two of the n zones.

14: The manufacturing method according to claim 1, wherein the synthesis further results from injection operations of a flux of at least one reactive fluid in at least one of the n zones.

15: The manufacturing method according to claim 14, wherein the reactive fluid is selected from the group consisting of water (H₂O), ammonia (NH₃), nitrogen (N₂), dihydrogen (H₂), acetylene (C₂H₂), methane (C₂H₄), ethylene (CH₃) and carbon dioxide (CO₂).

16: A device for implementing the method according to claim 1, the device comprising:
an enclosure, provided with an inlet and an outlet through which the support enters and exits respectively;
a reaction chamber, located in an enclosure between the inlet and the outlet, and divided into the n zones, along the conveying direction; and
a conveyer conveying, along the conveying direction, the support from the inlet to the outlet of the enclosure passing through the reaction chamber;
wherein each zone is equipped with:
a first injecting system for injecting, in an associated zone, a flux of the aerosol containing the catalytic precursor and the source precursor of the material of the nanostructures to be formed, conveyed by the carrier gas;
a first individual heating element, configured to heat the substrate upon passing in the associated zone; and
a second individual heating element, configured to heat the aerosol injected in the associated zone.

17: The device according to claim 16, wherein at least two of the n first injecting systems are configured to inject the aerosol with a parameter selected from the group consisting of a carrier gas flow rate and a mass concentration of the catalytic precursor in the catalytic precursor and source precursor mixture, which is different.

18: The device according to claim 16, wherein at least one of the n zones is further equipped with a second injecting system for injecting, into the associated zone, a flux of at least one reactive fluid.

19: The device according to claim 18, wherein at least two of the n zones are equipped with the second injecting system and at least two of these second injecting systems are configured to inject the reactive fluids, into the associated zones, with a parameter selected from the group consisting of a flow rate of the reactive fluids, a chemical composition and a concentration of different components of the reactive fluids, which is different.

20: The device according to claim 16, further comprising
an injection controller, associated with each first injecting system, which is designed to trigger an injection of flux of an aerosol into the associated zone when the support penetrates this zone and keep this injection until the support exits from this zone.

21: The device according to claim 16, wherein at least two adjacent zones are separated from each other by a partition wall having an aperture allowing the support to pass therethrough, containing preventer at the aperture for preventing fluids and aerosols from passing from one zone to the other.

22: The device according to claim 16, wherein the enclosure farther includes a pre-treatment chamber, which is located upstream of the reaction chamber, along the conveying direction of the support, and which is provided with an inlet and an outlet through which the support enters and exits respectively, the pre-treatment chamber being equipped with a system for injecting a fluid and heating components.

23: The device according to claim 16, wherein the enclosure further includes a post-treatment chamber, which is located downstream of the reaction chamber, along the conveying direction of the support, and which is provided with an inlet and an outlet through which the support enters and exits respectively, the post-treatment chamber being equipped with a system for injecting a fluid and heating components.
